(19) United States
(12) Patent Application Publication
(10) Pub. No.: US 2025/0247055 A1
(43) Pub. Date: Jul. 31, 2025

(54) TECHNIQUES FOR DIGITAL-DOMAIN TEMPERATURE COMPENSATION IN LOGARITHMIC TRANSIMPEDANCE AMPLIFIER DEVICES

(71) Applicant: Analog Devices, Inc., Wilmington, MA (US)

(72) Inventors: Petrus M. STROET, Santa Cruz, CA (US); Eberhard BRUNNER, Santa Barbara, CA (US)

(21) Appl. No.: 18/422,920

(22) Filed: Jan. 25, 2024

(51) Int. Cl. H03F 1/32; H03F 3/45

(52) U.S. Cl. CPC H03F 1/3211; H03F 3/45085; H03F 3/45174; H03F 3/45273; H03F 2200/372

(57) ABSTRACT

Technologies are provided to calculate a logarithm of an input current to a logarithmic transimpedance amplifier device at a particular temperature. The logarithm of the current is calculated in digital domain based on sampling of analog signals that are internal to the logarithmic transimpedance amplifier device. The sampling can be performed, in some cases, by an analog-to-digital converter device integrated into the logarithmic transimpedance amplifier device. The calculation in digital domain is performed by one or more processor external to the logarithmic transimpedance amplifier device. The calculation includes a determination of a temperature compensation factor based on an internal analog signal indicative of temperature of the logarithmic transimpedance amplifier device. The temperature compensation factor permits removing temperature dependence from a logarithmic output voltage originating from the input current. Operating in the digital domain permits applying corrections that account for residual leakage current and an emitter-resistance correction at high input currents.

### BACKGROUND

An optical log converter (or optolog converter) is a device used to measure optical power using a photodiode that generates an output current that increases with the optical power. The generated output current has a dynamic range that is twice (in dB) the optical input power dynamic range and can have spans several orders of magnitude. For example, the input current can range from about 100 pA to about 10 mA. Optolog converters are adequate for such measurements because an optolog converter includes a logarithmic transimpedance amplifier (TIA) device that relies on the logarithmic relationship between base-emitter voltage and collector current of bipolar junction transistors. Such a logarithmic relationship compresses the several orders of magnitude within the dynamic range of the optical input power.

However, the base-emitter voltage difference between the logarithmic TIA device connected to an input channel and the logarithmic TIA device connected to a reference channel is proportional to absolute temperature of the logarithmic transimpedance amplifier integrated into the optolog converter. Accordingly, a voltage output of the logarithmic transimpedance amplifier is compensated for temperature in order to have a voltage output that is independent of temperature. Existing technologies implement such temperature compensation using analog circuitry. The analog circuitry, however, can introduce errors that impede an accurate determination of an input current based on the voltage output.

Therefore, several technical challenges remain in technologies for temperature compensation in logarithmic transimpedance amplifiers. Improved technologies that address those challenges are desirable.

### SUMMARY

In an aspect, the present disclosure provides a device. The device includes a logarithmic transimpedance amplifier device configured to: generate one or more first digital signals during a first time interval, each of the one or more first digital signals corresponding to an analog thermometer signal that is proportional to a temperature of the logarithmic transimpedance amplifier device; generate one or more second digital signals during a second time interval, each of the one or more second digital signals corresponding to an analog voltage signal that is logarithmically proportional to an input current received at the logarithmic transimpedance amplifier device; and generate one or more third digital signals during a third time interval, each of the one or more third digital signals corresponding to a second analog voltage signal that is logarithmically proportional to a reference current generated by the logarithmic transimpedance amplifier device. The device also includes a processor functionally coupled with the logarithmic transimpedance amplifier device, the processor being configured to determine, using the one or more first digital signals, the one or more second digital signals, and the one or more third digital signals, a logarithmic ratio of the input current and the reference current.

In another aspect, the present disclosure provides a device. The device includes a logarithmic transimpedance amplifier device configured to: generate multiple first digital signals during respective first time intervals, each one of the multiple first digital signals corresponding to a respective analog thermometer signal that is proportional to a temperature of the logarithmic transimpedance amplifier device; generate multiple second digital signals during respective second time intervals, each one of the multiple second digital signals corresponding to a respective analog voltage signal that is logarithmically proportional to a respective input current received at the logarithmic transimpedance amplifier device; and generate multiple third digital signals during respective third time intervals, each one of the multiple third digital signals corresponding to a respective second analog voltage signal that is logarithmically proportional to a respective reference current generated by the logarithmic transimpedance amplifier device. The device also includes a processor functionally coupled with the logarithmic transimpedance amplifier device, the processor being configured to determine, using the multiple first digital signals, the multiple second digital signals, and the multiple third digital signals, respective logarithmic ratios of input current and reference current.

In yet another aspect, the present disclosure provides a device. The device includes a logarithmic transimpedance amplifier device configured to: generate an analog thermometer signal that is proportional to a temperature of the logarithmic transimpedance amplifier device; generate an analog voltage signal logarithmically proportional to respective input currents received at the logarithmic transimpedance amplifier device; and generate a second analog voltage signal logarithmically proportional to respective reference currents generated by the logarithmic transimpedance amplifier device. The device also outputs the analog thermometer signal, the analog voltage signal, and the second analog voltage signals.

In a further aspect, the present disclosure provides a system including: a first device configured to: generate an analog thermometer signal that is proportional to a temperature of the first device; generate an analog voltage signal logarithmically proportional to an input current received at the first device; generate a second analog voltage signal logarithmically proportional to a reference current generated by the first device; and output the analog thermometer signal, the analog voltage signal, and the second analog voltage signals. The system also includes a second device configured to: receive the analog thermometer signal, the analog voltage signal, and the second analog voltage signals; generate one or more first digital signals during a first time interval, each of the one or more first digital signals corresponding to the analog thermometer signal; generate one or more second digital signals during a second time interval, each of the one or more second digital signals corresponding to the analog voltage signal; generate one or more third digital signals during a third time interval, each of the one or more third digital signals corresponding to the second analog voltage signal; and determine, using the one or more first digital signals, the one or more second digital signals, and the one or more third digital signals, a logarithmic ratio of the input current and the reference current.

In another aspect, the present disclosure provides a system including: a first device configured to: generate an analog thermometer signal that is proportional to a temperature of the first device; generate analog voltage signals logarithmically proportional to respective input currents received at the first device; generate second analog voltage signals logarithmically proportional to respective reference currents generated by the first device; and output the analog thermometer signal, the analog voltage signals, and the second analog voltage signals. The system also includes a second device configured to: receive the analog thermometer signal, the analog voltage signals, and the second analog voltage signals; generate one or more first digital signals during a first time interval, each of the one or more first digital signals corresponding to the analog thermometer signal; generate one or more second digital signals during a second time interval, each of the one or more second digital signals corresponding to a particular one of the analog voltage signals; generate one or more third digital signals during a third time interval, each of the one or more third digital signals corresponding to a particular one of the second analog voltage signals; and determine, using the one or more first digital signals, the one or more second digital signals, and the one or more third digital signals, a logarithmic ratio of a particular one of the respective input currents and a particular one of the respective reference currents.

In yet another aspect, the present disclosure provides a method including: generating, by a device comprising an amplifier device and a processor, one or more first digital signals during a first time interval, each of the one or more first digital signals corresponding to an analog thermometer signal that is proportional to a temperature of the amplifier device; generating, by the device, one or more second digital signals during a second time interval, each of the one or more second digital signals corresponding to an analog voltage signal that is logarithmically proportional to an input current received by the amplifier device; generating, by the amplifier device, a reference current; generating, by the device, one or more third digital signals during a third time interval, each of the one or more third digital signals corresponding to a second analog voltage signal that is logarithmically proportional to the reference current; and determining, by the device, using the one or more first digital signals, the one or more second digital signals, and the one or more third digital signals, a logarithmic ratio of the input current and the reference current.

In a still further aspect, the present disclosure provides a method including generating, by an amplifier device, an analog thermometer signal that is proportional to a temperature of the amplifier device; generating, by an amplifier device, analog voltage signals logarithmically proportional to respective input currents received at the amplifier device; generating, by the amplifier device, second analog voltage signals logarithmically proportional to respective reference currents generated by the first device; and outputting, by the amplifier device, the analog thermometer signal, the analog voltage signals, and the second analog voltage signals.

This Summary is not intended to emphasize any particular aspects of the technologies of this disclosure. Nor is it intended to limit in any way the scope of such technologies. This Summary simply covers a few of the many aspects of this disclosure as a straightforward introduction to the more detailed description that follows.

### BRIEF DESCRIPTION OF THE DRAWINGS

The accompanying drawings form part of the disclosure and are incorporated into the subject specification. The drawings illustrate example aspects of the disclosure and, in conjunction with the following detailed description, serve to explain at least in part various principles, features, or aspects of the disclosure. Some aspects of the disclosure are described more fully below with reference to the accompanying drawings. However, various aspects of the disclosure can be implemented in many different forms and should not be construed as limited to the implementations set forth herein. Like numbers refer to like elements throughout.

FIG. 1 is a block diagram of an example of a device to determine an input current to a transimpedance amplifier device at a particular temperature, where the input current is responsive to optical input power, in accordance with one or more aspects of this disclosure.

FIG. 2 is an electric circuit diagram of an example of a logarithmic current-to-voltage converter device integrated into the device shown in FIG. 1, in accordance with one or more aspects of this disclosure.

FIG. 3 is an electric circuit diagram of an example of a current digital-to-analog converter (IDAC) device integrated into the device shown in FIG. 1, in accordance with one or more aspects of this disclosure.

FIG. 4 is an electric circuit diagram of an example of a current generator device integrated into the device shown FIG. 1, in accordance with one or more aspects of this disclosure.

FIG. 5A is an electric circuit diagram of an example of temperature sensing circuitry integrated into the device shown in FIG. 1, in accordance with one or more aspects described herein.

FIG. 5B is an electric circuit diagram of another example of temperature sensing circuitry integrated into the device shown in FIG. 1, in accordance with one or more aspects described herein.

FIG. 6 is a block diagram of an example of signal processing circuitry integrated into the device shown in FIG. 1, in accordance with one or more aspects described herein.

FIG. 7 presents plots of logarithmic ratio of input current and reference current as a function of input current in an example of the device shown in FIG. 1, in accordance with one or more aspects of this disclosure.

FIG. 8 is a plot of logarithmic conformance as a function of input current in a channel of an example of the device shown in FIG. 1, in accordance with one or more aspects of this disclosure.

FIG. 9 is a block diagram of an example of packaging of the device shown in FIG. 1, in accordance with one or more aspects of this disclosure.

FIG. 10 is a block diagram of another example of packaging of the device shown in FIG. 1, in accordance with one or more aspects of this disclosure.

FIG. 11 is a block diagram of another example of a device to determine an input current to a transimpedance amplifier device at a particular temperature, where the input current is responsive to optical input power, in accordance with one or more aspects of this disclosure.

FIG. 12 is a flowchart of an example method for determining a logarithm of an input current to a logarithmic transimpedance amplifier device at a particular temperature, in accordance with one or more aspects of this disclosure.

FIG. 13 is a flowchart of an example method for supplying analog signals that can be used to determine a logarithm of an input current to a logarithmic transimpedance amplifier device at a particular temperature, in accordance with one or more aspects of this disclosure.

FIG. 14 is a flowchart of another example method for determining a logarithm of an input current to a logarithmic transimpedance amplifier device at a particular temperature, in accordance with one or more aspects of this disclosure.

### DETAILED DESCRIPTION

The present disclosure recognizes and addresses, among other technical challenges, the issue of temperature compensation of the voltage output of a logarithmic TIA device. The logarithmic TIA device relies on the logarithmic relationship between base-emitter voltage and collector current of bipolar junction transistors. However, the base-emitter voltage difference between the logarithmic TIA device connected to an input channel and the logarithmic TIA device connected to a reference channel is proportional to absolute temperature of the logarithmic TIA device. Accordingly, a voltage output of the logarithmic transimpedance amplifier is compensated for temperature in order to have a voltage output that is independent of temperature. Existing technologies implement such temperature compensation using analog circuitry. The analog circuitry, however, can introduce errors that impede an accurate determination of an input current based on the voltage output. Embodiments of the technologies described herein avoid such errors by performing temperature compensation in digital domain.

Embodiments of the technologies disclosed herein include systems, devices, and methods that, individually or in combination, can be used to calculate a logarithm of an input current to a logarithmic transimpedance amplifier device that is temperature independent. Rather than compensating the temperature-dependent gain of a logarithmic TIA using analog circuitry, the input current to a logarithmic transimpedance amplifier can be calculated using a thermometer signal such that it is temperature independent. More specifically, the logarithm of the current is calculated in digital domain based on sampling of analog signals that are internal to the logarithmic transimpedance amplifier device. The sampling can be performed by an analog-to-digital converter (ADC). The calculation in digital domain is performed by one or more processor external to a chipset that contains the logarithmic transimpedance amplifier device. The calculation includes a determination of a temperature compensation factor based on a third internal analog signal indicative of temperature of the logarithmic amplifier device. The temperature compensation factor permits removing temperature dependence from a logarithmic output voltage originating from the input current. The logarithmic transimpedance amplifier device includes one or multiple channels, each channel receiving an input current and causing the processor(s) to determine a respective temperature compensation factor and a respective logarithm of the input current that is independent of temperature.

By performing temperature compensation in digital domain, embodiments of the technologies disclosed herein provide superior performance and flexibility relative to commonplace technologies. For example, embodiments of the technologies described herein can implement various adjustments to the calculation of the logarithm of an input current. The application of one or more adjustments (or compensations) can provide a more accurate value of the input current. An example of an adjustment (or compensation) includes subtraction of a defined current from an initial input current obtained from the logarithmic ratio of input current and reference current. Another example of an adjustment (or compensation) includes an emitter compensation at high input currents. Commonplace technologies that perform temperature compensation using analog circuitry are unable to implement some of those corrections accurately.

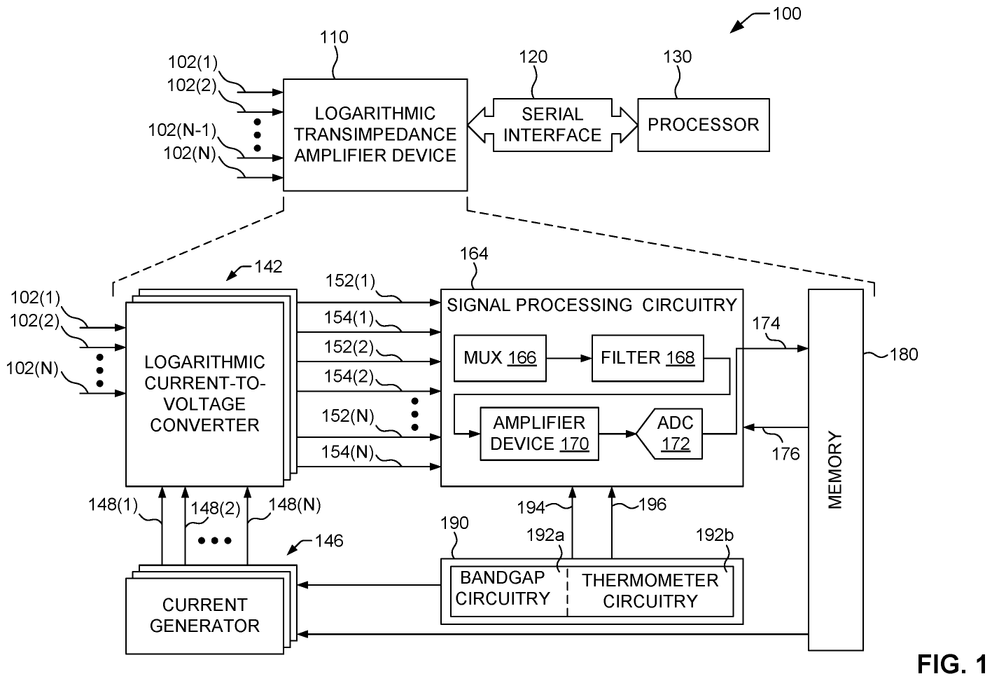

FIG. 1 is a block diagram of an example of a device 100 to determine a logarithm of an input current to a logarithmic transimpedance amplifier device, where the current is responsive to an optical input power, in accordance with one or more aspects of this disclosure. The current is generated by a photodetector (such as a photodiode; not depicted in FIG. 1) and can be proportional to the optical input power. The dynamic range of the current is thus two times (in terms of dB) the dynamic range of the optical input power. The dynamic range can be substantial. For example, the current responsive to the optical input power can range from about 100 pA to about 10 mA. That is, depending on the amount of optical power, the current can exhibit a 160 dB variation.

The device 100 includes a logarithmic transimpedance amplifier device 110 (also referred to as amplifier device 110, for the sake of simplicity). In some cases, the amplifier device 110 is a multi-channel amplifier device that can process multiple input currents, including a first input current 102(1), a second input current 102(2), up to an (N−1)-th input current 102(N−1), and an N-th input current 102(N). Although N is illustrated in FIG. 1 as being greater than two, the disclosure is not limited in that respect. In some cases, the amplifier device 110 is a two-channel amplifier device (that is, N=2). In other cases, rather than having multiple channels, the amplifier device 100 is a single-channel amplifier device (that is, N=1).

Each input current 102(k) can be denoted by I_{INP}^{(k)}, where k is an index that identifies a channel of the amplifier device 110 and k=1, 2, . . . N. For each input current I_{INP}^{(k)} the amplifier device 110 can generate a respective pair of voltage signals including a first voltage signal and a second voltage signal. The first voltage signal can be denoted by V_{E}^{(k)}, and the second voltage signal can be referred to as reference voltage and can be denoted by V_{EREF}^{(k)}. To generate the respective pair of voltage signals, as illustrated in FIG. 1, the amplifier device 110 includes multiple logarithmic current-to-voltage converter devices 142 and multiple current generator devices 146. Each one of the multiple logarithmic current-to-voltage converter devices 142 can receive an input current 102(k) and can generate a first voltage 152(k) and a second voltage 154(k). The first voltage 152(k) can correspond to V_{E}^{(k)} and the second voltage 154(k) can correspond to V_{EREF}^{(k)} or vice versa. To generate the first voltage 152(k) and the second voltage 154(k), a current-to-voltage converter device receives a reference current 148(k) from a particular current generator device (e.g., the k-th current generator device) of the multiple current generator devices 146. The reference current 148(k) depends on temperature, and a magnitude of the reference current 148(k) can be calibrated in order to attain a residual correction. In some cases, each reference current 148(k) has a same magnitude. Such a magnitude is 1 μA, for example.

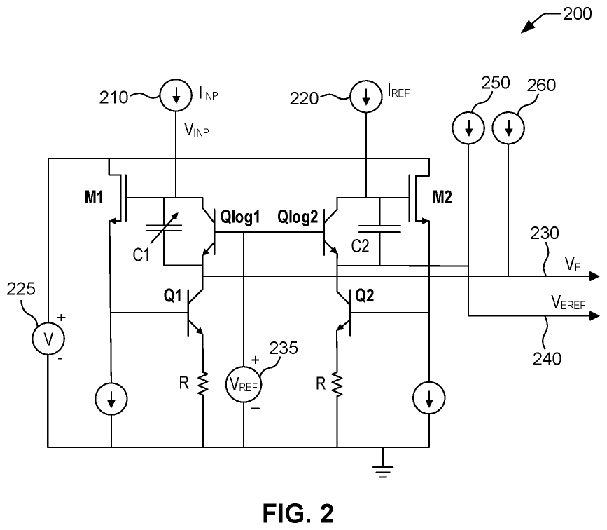

FIG. 2 is an electric circuit diagram of an example of a current-to-voltage converter device 200 that can embody each one of the multiple logarithmic current-to-voltage converter devices 142. The current-to-voltage converter device 200 receives an input current 210 (denoted by I_{INP}) and a reference current 220 (denoted by I_{REF}). The input current 210 can be one of the input currents 102(1)-102(N) (FIG. 1), and the reference current 220 is one of the reference currents 148(1)-148(N). The input current 210 can range from about 100 pA to about 10 mA. The reference current 220 is about 1 μA, for example.

The current-to-voltage converter device 200 includes a first loop having a transistor M1, a transistor Qlog1, and a transistor Q1. As is illustrated, M1 is an N-type MOS transistor (NMOS) and transistors Qlog1 and Q2 are N-type bipolar junction transistors. The collector current and the base-emitter voltage of Qlog1 exhibit a log-linear relationship over many decades. In that first loop, the collector current is equal to the input current I_{INP}. The base-emitter voltage of Qlog1 is a first voltage signal 230 that is supplied by the current-to-voltage converter device 200. The first voltage signal 230 is denoted herein by V_{E}. Further, the first loop includes a programmable capacitor C1 that can reduce noise in the collector of Q1. As is illustrated in FIG. 2, the current-to-voltage converter device 200 also can include a first bias current 250 and a second bias current 260. The first bias current 250 can determine, at least partially, a voltage gain around Q2. A ratio of the first bias current 250 and the reference current 220 is an estimate of the voltage gain around Q2. The second bias current 260 can determine, at least partially, a voltage gain around Q1. A ratio of the second bias current 260 and the input current 210 is an estimate of the voltage gain around Q1. In implementations where one or more of those bias currents are relatively large (e.g., about 1 mA to 10 mA), the programmable capacitor C1 can be configured to have a capacitance that provides a trade-off between speed and broadband output noise of current-to-voltage converter device 200. In low-power implementations (e.g., small bias current 250 and small bias current 260) the programmable capacitor C1 can be configured to a relatively high value so as to maintain the current-to-voltage converter device 200 stable as the input current 210 changes. Capacitance of C1 in such low-power implementations can range from about 0.2 pF to 0.6 pF, for example. In some configurations, however, the capacitor C1 can be excluded from the first loop. The current-to-voltage converter device 200 includes a power supply 225 that energizes the first loop by providing a DC voltage V (e.g., 2.4 V).

The current-to-voltage converter device 200 also includes a second loop having a transistor M2, a transistor Qlog2, and a transistor Q2. As is illustrated in FIG. 2, M2 is an N-type MOS transistor, and transistors Qlog2 and Q2 are N-type bipolar junction transistors. The collector current of Qlog2 is equal to the reference current 220 and is used to compensate for the strongly temperature-dependent saturation current (Is) of Qlog1. As such, a change in the reference current 220 (I_{REF}) results in a change in the first voltage signal 230. Regardless of the magnitude of I_{REF}, the base-emitter voltage of Qlog2 is a second voltage signal 240 that is supplied by the current-to-voltage converter device 200. The second voltage signal 240 is denoted herein by V_{EREF}. Further, the second loop includes a capacitor C2 that can reduce noise in the collector of Q2. Capacitance of the capacitor C2 can be relatively high (e.g., about 1.6 pF to about 5 pF) in order to mitigate crosstalk from the first loop in the current-to-voltage converter device 200. The current-to-voltage converter device 200 includes a power supply 235 that energizes the second loop by providing a DC voltage V_{REF} (e.g., 1.6 V) that is derived from a replica circuit which tracks V_{INP} with temperature.

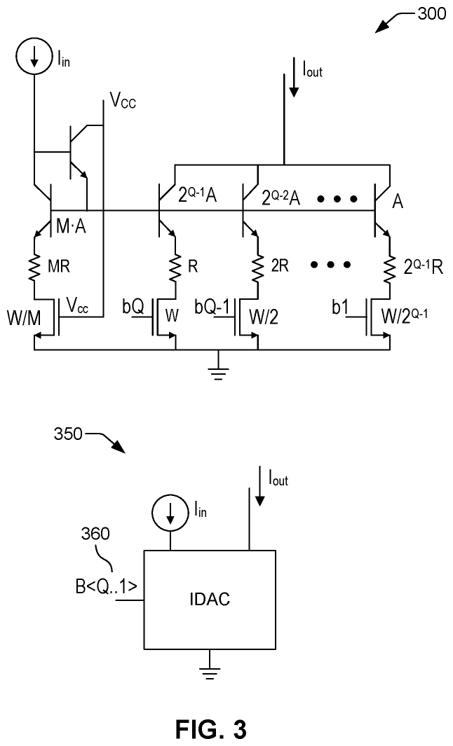

The reference current 220 (FIG. 2) is configurable and can be generated based on a combination of digital data (or digital signals), e.g., two or more strings of bits, where each string is referred to as a “word” and has a respective number of bits that defines the size of the word. As such, each one of the current generator devices 146 can include one or more current digital-to-analog (DAC) converter devices. As an illustration, FIG. 3 presents an electric circuit diagram of an example of a multiplying current DAC converter device 300 that is included in each one of the current generator devices 146. FIG. 3 also presents a symbolic diagram 350 of the device 300. The multiplying current DAC device 300 is a Q-bit DAC, and can be referred to as IDAC device 300. That is, as is shown in the symbolic diagram 350, the IDAC 300 can receive a configurable Q-bit word 360 and can output a current Iout that is based on both an input current Iᵢₙ and the word 360. The Q-bit word 360 can be represented as b_{Q}b_{Q-1} . . . b₁, where by is equal to 1 or 0 (j=1, 2, . . . Q) and defines a weight factor in the IDAC device 300. To define the weight factor, the value of bⱼ sets a gate of a respective MOS transistor in the IDAC device 300 to either high (1) or low (0). The configurable Q-bit word 360 can be calibrated and retained within a non-volatile memory (NVM) device within one or more memory devices 180 (FIG. 1; collectively referred to as memory 180). In some cases, besides including one or more NVM devices, the memory 180 also includes one or more buffers.

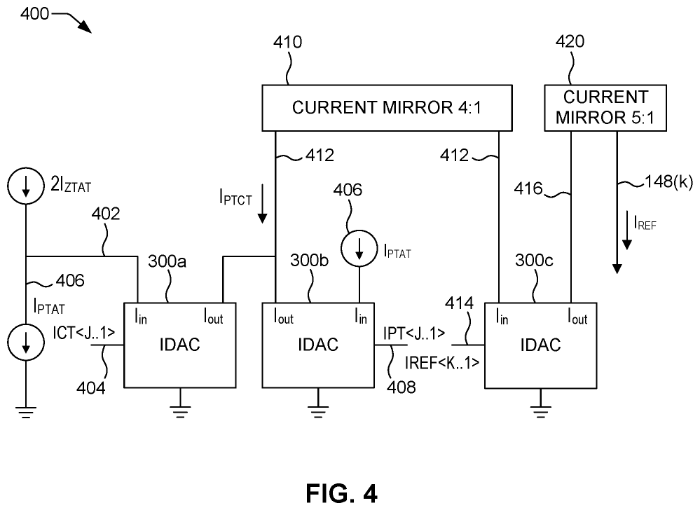

In some cases, each one of the multiple current generator devices 146 (FIG. 1) includes an electronic circuit 400 as is illustrated in FIG. 4. Accordingly, each one of the current generator devices 146 includes a first IDAC device 300a, a second IDAC device 300b, and a third IDAC device 300c. Further, each one of the current generator devices 146 also includes a first current mirror 410 and a second current mirror 420. As is illustrated in FIG. 4, the first current mirror 410 and the second current mirror 420 have respective ratios that decrease output current. Current mirrors having such ratios are used to maintain the area of the resistors R, 2R . . . 2^{(Q-1)}R in the example circuit 300 (FIG. 3) reasonably low by being able to configure the example circuit 300 with lower resistor values. That is, the area of each one of the resistors R, 2R, . . . 2^{(Q-1)}R divided by the area of respective transistors coupled therewith can be maintained at reasonably low values. A reasonably low value of the ratio of area of resistor to area of transistor is less than or equal to about 5, in some configurations. Simply as an illustration, examples of ratios are 5:1, 4; 1, 3:1, and 2:1. The disclosure, of course, is not limited to the example ratios 5:1 and 4:1 that are illustrated in FIG. 4. As mentioned, for each channel k (1, 2, . . . N), a respective one of the current generator devices 146 (FIG. 1) generates and supplies a reference current 148(k) (denoted by I_{REF} in FIG. 4).

The reference current I_{REF} in FIG. 4 is generated by using a scaled proportional-to-absolute temperature (PTAT) current 406 (denoted by I_{PTAT}) and a constant current I_{ZTAT}. Here, I_{ZTAT} is a constant current versus temperature in absolute temperature, referred to as zero change to absolute temperature (ZTAT) current. More specifically, the reference current 148(k) is generated, at least in part, by adding the scaled I_{PTAT} and a scaled current 402 that is equal to 2I_{ZTAT}−I_{PTAT}. The scaled current 402 is denoted by a complementary to absolute temperature (CTAT) current I_{CTAT}, which is a current with a negative temperature coefficient. To add the scaled PTAT current 406 and the scaled current 402, the first IDAC device 300a receives a digital signal 404 defining a first J-bit word that configures the weight factors for the analog-to-digital conversion of the scaled current 402, and the second IDAC device 300b receives a digital signal 408 defining a second J-bit word that configures the weight factors for the analog-to-digital conversion of the scaled PTAT current 406. The digital signal 404 (e.g., the first J-bit word) is referred to as ICT and the digital signal 408 (e.g., the second J-bit word) is referred to IPT. In some cases, the size of the first J-bit word and the second J-bit word 408 is seven bits. By using 7-bit DACs driven by digital signals IPT and ICT, a fine portion of the reference current 148(k) can be configured. Irrespective of word size, the configurations of weight factors, via ICT and IPT, determine a slope of the reference current 148(k) as a function of temperature. Such a slope represents the temperature drift of the reference current 148(k).

Adding the scaled PTAT current 406 and the scaled current 402 results in a current 412 (denoted by I_{PTCT} in FIG. 4). The current mirror 410 supplies the current 412 to the third IDAC device 300c. As is illustrated in FIG. 4, the third IDAC device 300c is a K-bit DAC driven by a digital signal 414 that configures the weight factors for the analog-to-digital conversion of the current 412 by the third IDAC device 300c. The digital signal 414 defines a K-bit word and is referred to as I_{REF}. The size of the K-bit word is less than the size of the J-bit word associated with the first IDAC device 300a and the second IDAC device 300b. Thus, the K-bit word configures a coarse portion of the reference current 148(k). In some cases, the K-bit DAC is a 4-bit DAC and the size of the K-bit word is four bits. The third IDAC device 300c outputs an analog current 416 to the second current mirror 420, where the analog current 416 defines the reference current 148(k). A current generator device of the multiple current generator devices 146, via the current mirror 420, supplies the reference current 148(k).

Each one of ICP, IPT, and IREF can be calibrated such that each one of the current generator devices 146 produces a reference current 148(k) (k=1, 2, . . . N) having a desired magnitude. For example, as is described herein, each reference current 148(k) can have a magnitude of approximately 1 μA. Multiples values of ICP, multiple values of IPT, and multiple values of IREF can be retained in respective registers within the memory 180 (FIG. 1).

With further reference to FIG. 2, for each one of Qlog1 and Qlog2, the emitter-to-base voltage can be expressed as

$${V}_{E B} = \frac{- {k}_{B} T}{q} ln ( \frac{I}{{I}_{S}} ) ,$$

where I=I_{INP} for Qlog1 and I=I_{REF} for Qlog2; k_{B} is Boltzmann's constant; q is the electron charge; T is the absolute temperature in Kelvin; I_{S} is the transistor saturation current; and ln(⋅) is the natural logarithm function. In situations where I>>I_{S}, V_{EB} can be approximated by

$$\frac{{k}_{B} T}{q} ln ( \frac{{I}_{S}}{I} ) .$$

Accordingly, assuming that I>>I_{S}, the voltage difference between the second voltage signal 240 (V_{EREF}) and the first voltage signal 230 (V_{E}) can be expressed as follows:

$${V}_{E R E F} - {V}_{E} = \frac{{k}_{B} T}{q} ln ( \frac{{I}_{INP}}{{I}_{R E F}} ) \qquad ( 1 )$$

The foregoing expression can be rewritten as

$${V}_{EREF} - {V}_{E} = \frac{ln ( 10 )}{20} ( \frac{{k}_{B} T}{q} ) 20 log ( \frac{{I}_{INP}}{{I}_{R E F}} ) \qquad ( 2 )$$

where log(⋅)=log₁₀(⋅) is the common logarithm function. Thus, by defining the ratio of I_{INP} and I_{REF} in dB as

$${ρ}_{d B} = 20 log ( \frac{{I}_{INP}}{{I}_{R E F}} ) ,$$

such a ratio can be obtained from a product of (i) a temperature compensation factor that is inversely proportional to absolute temperature and (ii) the difference between the second output signal 240 and the first output signal 230; namely:

$${ρ}_{d B} = \frac{1}{T} ( \frac{20 q}{{k}_{B} ln ( 10 )} ) ( {V}_{E R E F} - {V}_{E} ) \qquad ( 3 )$$

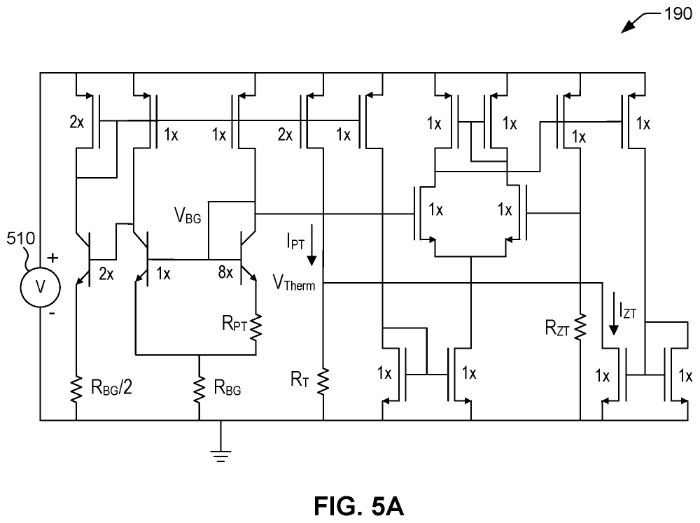

The formalism above in connection with Eqs. (1)-(3) apply to each channel k of the amplifier device 110. Therefore, for each channel k (1, 2, . . . N), provided the reference current 148(k), the input current I_{INP}^{(k)} at temperature T can be determined directly from the first voltage signal 152(k) and the second voltage signal 154(k) and a value of the temperature. As such, the amplifier device 110 includes sensing circuitry 190 that can generate and supply a voltage 194 that is representative of the temperature T. The voltage 194 is an analog signal and is denoted by Vₜₕₑᵣₘ. To that end, the sensing circuitry 190 includes first circuitry 192a and second circuitry 192b. The first circuitry 192a forms a bandgap reference generator and the second circuitry 192b forms an analog thermometer. In some cases, as is illustrated in FIG. 5A, the sensing circuitry 190 is configured to generate a voltage 194 (V_{Therm}) that is proportional to temperature by outputting a current I_{PT} to a resistor R_{T}. The current I_{PT} is a proportional-to-absolute-temperature (PTAT) current. In the sensing circuitry 190 illustrated in FIG. 5A, the bandgap reference generator supplies the current I_{PT}. Additionally, a current I_{ZT} is subtracted from the current I_{PT} in order to afford more sensitivity to V_{Therm} in terms of mV/° C. in available voltage headroom. Currents I_{PT} and I_{ZT} are, respectively, the current I_{PTAT} and I_{ZTAT} used by the electronic circuit 400 (FIG. 4) included in each one of the current generator devices 146 (FIG. 1). The sensing circuitry 190 is energized by a power supply 510 that provides a DC voltage V (e.g., 2.6 V).

As is described herein, V_{Therm} generated by the sensing circuitry 190 shown in FIG. 5A can be calibrated by adding a digital value TC to an analog-to-digital-converted reading of V_{Therm} (the voltage 194). Such a calibration is referred to as digital V_{Therm} calibration. In other configurations of the sensing circuitry 190, as is illustrated in FIG. 5B, the sensing circuitry 190 is configured to generate a voltage 194 (V_{Therm}) that can be calibrated in analog fashion. The sensing circuitry 190 shown in FIG. 5B generates V_{Therm} by outputting an additional current I_{OUT} (besides I_{PT}) to the resistor R_{T}. FIG. 5B includes a U-bit IDAC device 520 that receives a current I_{ZR2} and subtracts a current I_{OUT} from I_{PT}. The resulting current I_{PT}-I_{ZT}-Iₒᵤₜ passes through the R_{T}, thus determining V_{Therm}. The current I_{OUT} can be determined, at least in part, by inputting a digital signal 530 and I_{ZT2} into the IDAC device 520. The digital signal 530 defines a U-bit word and is referred to as TC. By changing the digital signal 530, and thus the U-bit word and associated value, V_{Therm} can be calibrated. Such a calibration is referred to as analog calibration. In some implementations, the ratio of I_{ZT} and the current (TC_{MAX}+1)/2M is equal to about ⅛, which provides calibration amounts in a range from about −12.5% to about 12.5%. Here, TCₘₐₓ is the maximum (decimal) value of the U-bit word (or TC). As is described herein, the U-bit word is retained in a register within the memory 180 (FIG. 1).

It is noted that in some implementations of the amplifier device 110, the sensing circuitry 190 can be configured according to one of the circuitry shown in FIG. 5A or the circuitry shown in FIG. 5B. Both configurations permit calibration of the voltage 194 using a value of the TC register.

Additionally, with further reference to FIG. 1, the amplifier device 110 also includes signal processing circuitry 164 that can receive the voltage 194. The signal processing circuitry 164 also can receive, for each channel k (1, 2 . . . N), the first voltage 152(k) and the second voltage 154(k). As mentioned, the first voltage 152(k) and the second voltage 154(k) respectively correspond to V_{E}^{(k)} and V_{EREF}^{(k)} or vice versa.

In sharp contrast to commonplace technologies, rather than utilizing an analog temperature compensation circuit to remove temperature dependence from a measured difference V_{EREF}^{(k)}−V_{E}^{(k)} for channel k, the amplifier device 110 sequentially process the first voltage 152(k), the second voltage 154(k), and the voltage 194, and supplies a digital signal 174 to a processor 130 to determine a magnitude of the input current 102(k) regardless of temperature T. The digital signal 174 is supplied via a serial interface 120 that functionally couples the amplifier device 110 and the processor 130. Example of the serial interface 120 include inter-integrated circuit (I2C), serial peripheral interface (SPI), universal serial bus (USB), low-voltage differential signaling (LVDS) interface.

More specifically, at different times during the sequential process, the digital signal 174 is indicative of one of the first voltage 152(k), the second voltage 154(k), or the voltage 194. That is, during a first time interval, the digital signal 174 defines a first value indicative of the first voltage 152(k); during a second time interval, the digital signal 174 defines a second value indicative the second voltage 154(k); and during a third time interval, the digital signal 174 defines a third value indicative of the voltage 194. Each one of first, second, and third value can be a respective M-bit word, for example.

Any particular ordering of the first time interval, the second time interval, and the third time interval can be implemented. In other words, there is no preferred order to sample the first voltage 152(k), the second voltage 154(k), and the voltage 194. In some cases, the second time interval is after the first time interval, and the third time interval is after the second time interval. More specifically, the first time interval, the second time interval, and the third time interval are sequentially ordered according to a defined sequence. Such intervals also are pairwise consecutive; that is, for all possible pairs of time intervals, a particular one of the time intervals in the pair is consecutive to a second particular one of the time intervals in the pair.

The amplifier device 110 can retain, in the memory 180, the first value indicative of the first voltage 152(k), the second value indicative the second voltage 154(k), and the third value indicative of the voltage 194. The processor 130 can read the first, second, and third values from the memory 180, and can then determine, using the first, second, and third values, a magnitude of the input current 102(k). For example, the processor 130 can read the first, second, and third values from one or more buffers present in the memory 180. In cases where the serial interface 120 is an I2C interface, the buffer(s) are I2C buffers and the processor 130 can read such buffer(s) according to I2C protocol.

In some cases, rather than using a single first value, a single second value, and a single third value, the processor 130 can obtain multiple first values indicative of the first voltage 152(k), multiple second values indicative of the second voltage 154(k), and multiple third values indicative of the voltage 194. The processor 130 can obtain those values by reading, at a defined rate, from the memory 180 (the values can be retained in one or more I2C buffers, for example). The number of multiple first values and the number of multiple second values can be a same number U, and the number of third values can be another number V. In some configurations, U>V because the sensitivity of voltage 194 can be higher than the sensitivity of the first voltage 152(k) and the second voltage 154(k), for each channel k.

The processor 130 can then determine an average of the multiple first values, an average of the multiple second values, and an average of the third multiple values. The processor 130 can determine a magnitude of the input current 102(k), using the average of the multiple first values, the average of the multiple second values, and the average of the third multiple values, and Eq. (3). In some cases, the defined rate at which the processor 130 reads a value is 1/60 Hz. At such a rate, any ripples at an input current 102(k) of 60 Hz or 120 Hz can be cancelled by the averaging of the multiple first values, the multiple second values, and the third multiple values. Thus, increments of the input current 102(k) due to larger components of 60 Hz and decrements of the input current due to smaller components of 60 Hz can be effectively cancelled.

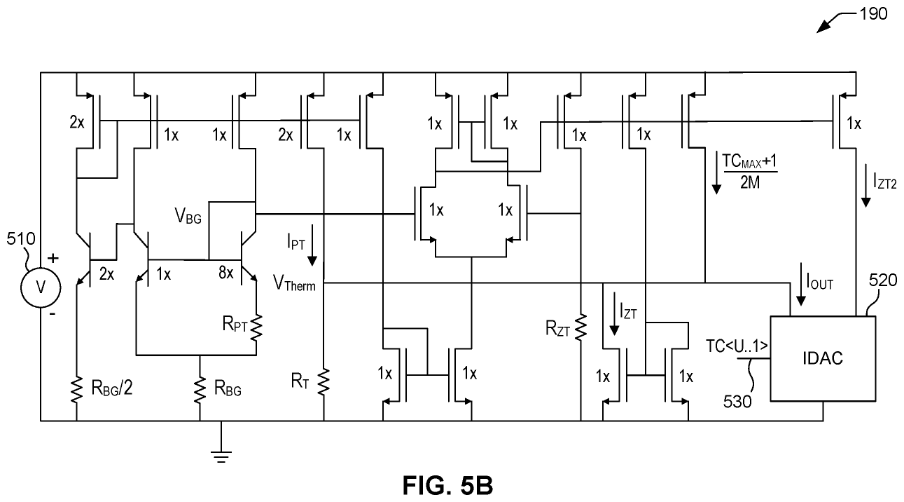

In order to sequentially process the first voltage 152(k), the second voltage 154(k), and the voltage 194 for channels 1 to N, in some cases, the signal processing circuitry 164 includes an analog multiplexer 166. The analog multiplexer 166 can sequentially select, for sampling, each one of the voltage 194, the first voltage 152(1), the second voltage 154(1), the first voltage 152(2), the second voltage 154(2), up to the first voltage 152(N), and the second voltage 154(N). To switch from a current voltage to a next voltage the analog multiplexer 166 can receive a control signal 176 from the processor 130, via the serial interface 120 and the memory 180. The control signal 176 is a digital datum, such as a string of bits (referred to as control bits). The digital datum can be retained in a control register within the memory 180. Different values of the control register can be retained in the memory 180 by the processor 130, via the serial interface 120. Each of those values causes the analog multiplexer 166 to point to (or select) a respective analog signal for sampling. Such an analog signal is one of the voltage 194, the first voltage 152(1), the second voltage 154(1), the first voltage 152(2), the second voltage 154(2), up to the first voltage 152(N), and the second voltage 154(N). Simply as an illustration, in the example of the signal processing circuitry 164 that is shown in FIG. 6, the analog multiplexer 166 is embodied in an analog multiplexer 610 that can switch among five input signals. The analog multiplexer 610 can be used in examples configurations where N=2.

Upon selecting an analog signal for sampling, the analog multiplexer 166 outputs the analog signal (e.g., a first voltage 152(m), with 1≤m≤N) to a filter 168. The filter 168 can serve as an anti-aliasing filter (AAF) that removes noise from the analog signal up to a defined threshold frequency (or bandwidth). Without an AAF, out-of-band noise can degrade signal quality at the output of the SAR ADC 640. The filter 168 can be an RC filter. Simply as an illustration, in the example of the signal processing circuitry 164 that is shown in FIG. 6, the filter 168 is embodied in an RC filter 620 formed by a capacitor C and a resistor R. The RC filter 620 serves as an AAF filter, in accordance with aspects of this disclosure. As such, the RC filter 620 is labeled “AAF” in FIG. 6. In one example configuration, the capacitor C has a capacitance that is equal to about 113 pF, and the resistor R has a resistance that is equal to about 283 kΩ. The relatively large value of the capacitance in such an example configuration is beneficial for the offset cancellation circuitry present in the auto-zero amplifier 630 included in the signal processing circuitry 164 shown in FIG. 6. More specifically, the performance of the offset cancellation circuitry is related to capacitance of C divided by the switch capacitance of the auto-zero amplifier 630. The resistance of the resistor R is typically adjusted to form an anti-aliasing filter with C at a corner point below the sample frequency divided by two. This disclosure is not limited to the values of capacitance and resistance in such an example configuration, and other values of capacitance of the capacitor C and resistance of the resistor R can be used in the RC filter 620. Indeed, the capacitance of the capacitor C can have any value within a range from about 10 pF to about 200 pF, and the resistance of the resistor R can have any value within a range from about 2 kΩ to about 400 kΩ.

The filter 168 (FIG. 1) outputs the analog signal that has been filtered to an amplifier device 170. In some cases, the amplifier device 170 is an auto-zero amplifier that has an input offset. While not shown in FIG. 1, the input offset can be retained in an offset capacitor or another type of storage component. The auto-zero amplifier can be used to reduce offsets in an analog signal that is output by the amplifier device 170. Simply as an illustration, in the example of the signal processing circuitry 164 that is shown in FIG. 6, the amplifier device 170 is represented by an auto-zero amplifier 630. In such an example, the offset capacitor (represented by C_{off}) is included and can have a capacitance equal to about 1.4 pF. Other capacitances can be contemplated.

As mentioned, in accordance with aspects of this disclosure, temperature compensation is performed in digital domain as opposed to using analog compensation circuitry. Consequently, the amplifier device 170 (FIG. 1) outputs the analog signal being sampled to an analog-to-digital converter 172 (ADC 172). The ADC 172 is an S-bit ADC. The ADC 172 can be a successive-approximation-register (SAR). The greater the value of S, the more accurate a reading of the analog signal. In some cases, the value of S and a sampling rate of the ADC 172 are suitable for integration on a same die as the other components of the amplifier device 110 and/or low power consumption. As such, in one example, the ADC 172 is a 14-bit ADC that has a processing rate of about 20 ksps. The disclosure is, of course, not limited in that respect and other sampling rates and/or conversion resolutions can be implemented. Simply as an illustration, on-chip sampling rates can vary from about 1 ksps to 10 Msps, with greater sampling rates causing greater power consumption. By being integrated on the same die as the other components of the amplifier device 110, the ADC 172 introduces a small on-chip capacitance and shares a same on-chip reference ground with other components. Thus, it may be desirable to integrate the ADC 172 in such fashion. In some cases, however, the ADC 172 can be assembled off-chip. In an example off-chip assembly, the ADC 172 can be integrated into the processor 130.

The ADC 172 is driven by a reference voltage 196 that can be supplied by the sensing circuitry 190. Changes in the reference voltage 196 can cause changes in the output (or reading) of the ADC 172. Thus, as is described herein, the sensing circuitry 190 includes the first circuitry 192a (referred to as bandgap circuitry 192a) that forms or constitutes a bandgap reference generator. The bandgap reference generator supplies a stable reference voltage 196. In some cases, the reference voltage 196 that drives the ADC 172 is equal to uV_{BG}, where u is a natural number (e.g., 2, 4, 6, or the like) and the voltage V_{BG} is generated by the bandgap reference generator.

Simply as an illustration, in the example of the signal processing circuitry 164 that is shown in FIG. 6, the ADC 172 is embodied in a SAR ADC 640 that can have 14-bit resolution. The reference voltage that drives the SAR ADC 640 is equal to 2V_{BG}. As mentioned, the disclosure is not limited in that respect and such a reference voltage can be another multiple of V_{BG}. The SAR ADC 640 outputs a 14-bit digital signal 650 (e.g., a 14-bit word). The ADC 640 receives an analog signal 638 (denoted by VOUT) to convert to a digital signal. Conversion of VOUT is referred to as a measurement and can occur during a track period (e.g., a 2.5 ρs period). Before a measurement of an input signal selected by the multiplexer 610, switch 1 and switch 2 are open and switch 3 and switch 4 are closed. The auto-zero amplifier 630 can include driver circuitry (not depicted) that controls switching. In such a state, voltage in the RC filter 620 capacitor C is ported to C_{off} in order to configure an offset that is approximately a correct value for the input signal. In an initial portion of the track period, switch 4 and switch 3 are open, and the auto-zero amplifier 630 is switched to a calibration mode by closing switch 1 and switch 2. In the calibration mode, an input 636 can control V_{OUT} and an offset can be calibrated to the value stored in C_{off}. In a subsequent portion of the track period, the auto-zero amplifier 630 can be switched to measurement mode by opening switch 1 and switch 2, and closing switch 3. In the measurement mode, the offset stored in C_{off} is provided to the operational amplifier 634, and the offset in VOUT can removed. In some cases, the operational amplifier 634 has unity gain.

As is described herein, for channel k (1, 2, . . . N), the digital signal 174 sequentially defines a first value indicative of the first voltage 152(k), a second value indicative the second voltage 154(k), and a third value indicative of the voltage 194. The first value corresponds to H_{E}^{(k)} and the second value corresponds to H_{EREF}^{(k)} or vice versa. The third value is denoted by H_{Therm}. For each channel k, the processor 130 can determine the difference between the first value and the second value. Such a difference can be defined as

$$Δ {H}^{( k )} = {Γ}_{A D C} ( {V}_{E R E F}^{( k )} - {V}_{E}^{( k )} ) = {H}_{E R E F}^{( k )} - {H}_{E}^{( k )} ,$$

where Γ_{ADC} is the gain of the ADC 172 expressed in units of least significant bits per volt (LSB/V), and the difference ΔH^{(k)} represents the digitized value of V_{EREF}^{(k)}−V_{E}^{(k)} obtained by means of the ADC 172 for channel k. Hence, from Eq. (2), ΔH^{(k)} can be expressed as:

$$Δ {H}^{( k )} = {Γ}_{A D C} ( \frac{ln ( 10 )}{20} ) ( \frac{{k}_{B} T}{q} ) {ρ}_{d B} \qquad ( 4 )$$

Accordingly, the third value H_{Therm} indicative of the voltage 194 (e.g., V_{Therm} in FIG. 5A) after digitation can be expressed as, in units of LSB/V:

$${H}_{T h e r m} = {Γ}_{A D C} ( \frac{{k}_{B} ln ( A ) {R}_{T}}{q {R}_{P T}} ) T - {Γ}_{A D C} {V}_{B G} ( \frac{{R}_{T}}{{R}_{Z T}} ) \qquad ( 5 )$$

where R_{T} is the thermometer load resistor (FIG. 5A and FIG. FIG. 5B) and R_{PT} is the resistor in the bandgap reference that sets the PTAT current I_{PT} (FIG. 5A), R_{ZT} is the resistor that sets the constant current I_{ZT}=V_{BG}/R_{ZT} (FIG. 5A), A denotes the area ratio of the bandgap (which ratio is 8 in the example in FIG. 5A)); and T is the temperature in Kelvin. From Eq. (5), H_{Therm} is negative at 0 K. Accordingly, an offset O can be added in order for the output of the thermometer value to be zero at 0 K. In this way, ΔE can be compensated with the absolute temperature T. Therefore, for compensation with the absolute temperature T,

$${H}_{T h e r m}^{( a b s )} = {Γ}_{A D C} ( \frac{{k}_{B} ln ( A ) {R}_{T}}{q {R}_{P T}} ) T - {Γ}_{A D C} {V}_{B G} ( \frac{{R}_{T}}{{R}_{Z T}} ) + 𝒪 \qquad ( 6 )$$

where at T=0 K,

$${H}_{T h e r m}^{( a b s )} ( 0 K ) = - {Γ}_{A D C} {V}_{B G} ( \frac{{R}_{T}}{{R}_{Z T}} ) + 𝒪 ≡ 0 \qquad ( 7 )$$

In the idealized scenario where the ADC 172 is an ideal S-bit ADC ranging from 0 to V_{REF} (the voltage that drives the ADC 172), Γ_{ADC}=2^{S}/V_{REF}. Thus, in case V_{REF}=2V_{BG}, the product Γ_{ADC}V_{BG}=2^{S-1} and the offset O is equal to

$${2}^{S - 1} ( \frac{{R}_{T}}{{R}_{Z T}} ) .$$

Therefore, in case V_{REF}=2V_{BG}, H_{Therm}^{(abs)} can be expressed as:

$${H}_{T h e r m}^{( a b s )} = {Γ}_{A D C} ( \frac{{k}_{B} ln ( A ) {R}_{T}}{q {R}_{P T}} ) T \qquad ( 8 )$$

As a result, in case V_{REF}=2V_{BG}, the ratio of ΔE and H_{Therm}^{(abs)} can be determined from Eqs. (4) and (8) and results in:

$$\frac{{H}_{E R E F}^{( k )} - {H}_{E}^{( k )}}{{H}_{T h e r m}^{( a b s )}} = \frac{{Γ}_{ADC} q ln ( 10 ) {R}_{P T} {k}_{B} T {ρ}_{d B}}{20 {Γ}_{A D C} q ln ( A ) {R}_{T} {k}_{B} T} = ( \frac{ln ( 10 ) {R}_{P T}}{20 ln ( A ) {R}_{T}} ) {ρ}_{d B} \qquad ( 9 )$$

As is described herein, V_{REF} can be equal to other multiples of V_{BG}, e.g., V_{REF}=uV_{BG}, yielding a similar expression to that in Eq. (9).

Because the offset O is equal to

$${2}^{S - 1} ( \frac{{R}_{T}}{{R}_{Z T}} )$$

in case V_{REF}=2V_{BG}, the processor 130 can determine ρ_{db}^{(k)} for channel k at temperature T using the following expression:

$${ρ}_{d B}^{( k )} = \frac{20 ln ( A ) {R}_{T}}{ln ( 10 ) {R}_{P T}} ( \frac{{H}_{E R E F}^{( k )} - {H}_{E}^{( k )}}{{H}_{T h e r m} + \frac{{2}^{S - 1} {R}_{T}}{{R}_{Z T}}} ) \qquad ( 10 )$$

That is, the processor 130 can determine the logarithmic ratio ρ_{dB}^{(k)} in dB of the input current 102(k) (k=1, 2, . . . N) to the reference current 146(k) by calculating the right-hand side of Eq. (10) using configured parameters A, R_{T}, R_{PT}, and R_{ZT} of the sensing circuitry 190 (see FIG. 5A) and measured values conveyed by the digital signal 174. It is noted that Eq. (10) is independent of the gain Γ_{ADC} of the ADC 172 and the bandgap voltage V_{BG}.

The amplifier device 110 can be configured to operate with a reference current of 1 μA. Accordingly, each one of the reference currents 148(1)-148(N) may be calibrated such that the processor 130 determines a pdB=0 for an input current of 1 μA. To that end, for each channel k (1, 2 . . . N), a coarse value that contributes to a reference current 148(k) (denoted by I_{REF}) can be calibrated by adjusting the value of I_{REF} (digital signal 414 in FIG. 4). In an example configuration where I_{REF} is a 4-bit word, the value of I_{REF} can be adjusted between 0 and 15. In addition, a fine value that also contributes to I_{REF} can be calibrated by adjusting a sum of the value of I_{PT} (digital signal 404 in FIG. 4) and the value of ICT (digital signal 408 in FIG. 4). The calibrated reference current 148(k) is the sum of the coarse value and the fine value. After each channel is calibrated, N values of IREF are stored in respective registers IREF1, IREF2, . . . and IREFN within the memory 180; N values of ICT are stored in respective registers ICT1, ICT2, . . . and ICTN within the memory 180; and N values of IPT are stored in respective registers IPT1, IPT2, . . . and IPTN within the memory 180. As an example, each value of IREF1, IREF2, . . . and IREFN can be equal to or about 10; each value of ICT1, ICT2, . . . and ICTN can be equal to or about 58; and each value of IPT1, IPT2, . . . and IPTN can be equal to or about 70.

Besides the calibration of the reference currents 148(1)-148(N), values of the voltage 194 provided by the thermometer included in the sensing circuitry 190 also can be calibrated with a particular TC value. Because the amplifier device 110 can be configured to operate with a reference current of 1 μA, the units of ρ_{dB} can be dBμA. Accordingly, in some cases, a temperature correction of 8(TC−128) is introduced in the expression of ρ_{dB}^{(k)} in units of dBμA (denoted by β_{dB}[dBμA]):

$${ρ}_{d B}^{( k )} [ dB μA ] = \frac{20 ln ( A ) {R}_{T}}{ln ( 10 ) {R}_{P T}} ( \frac{{H}_{E R E F}^{( k )} - {H}_{E}^{( k )}}{{H}_{T h e r m} + \frac{{2}^{S - 1} {R}_{T}}{{R}_{Z T}} + 8 ( T C - 128 )} ) \qquad ( 11 )$$

In Eq. (11), TC is an 8-bit register value between 0 and 255 that serves as a thermometer calibration. Using TC=128 does not introduce any offset. A factor of 8 is used as a trade-off between calibration range and resolution. Indeed, for each change of 1 in the decimal value of TC, a change of 0.16° C. can be attained, which is a satisfactory resolution. Additionally, the factor of 8 combined with the 8-bit register, yields a temperature range of approximately 41° C., which is a satisfactory calibration range.

To determine a satisfactory value of TC, for each channel k (1, 2, . . . N), a first input current I_{H} and a second input current I_{L} can be provided to each one of the devices of the logarithmic current-to-voltage converter devices 142. Here, I_{H} is much greater than I_{L} in order to ensure a large enough signal that can be measured with sufficient accuracy, although such a relationship is not a requirement for calibration. Additionally, a first value H_{EREF}^{(k)}(I_{H})−H_{E}^{(k)}(I_{H}) and a second value H_{EREF}^{(k)}(I_{L})−H_{E}^{(k)}(I_{L}) are measured at the output of the ADC172. Because the difference

$$Δ {ρ}_{d B} = {ρ}_{d B}^{( k )} [ dB μA ] ( {I}_{H} ) - {ρ}_{d B}^{( k )} [ dB μA ] ( {I}_{L} ) = 20 log ( {I}_{H} / {I}_{L} ) ,$$

the satisfactory value of TC can be obtained from Eq. (11) using H_{EREF}^{(k)}(I_{H})−H_{E}^{(k)}(I_{H}), H_{EREF}^{(k)}(I_{L})−H_{E}^{(k)}(I_{L}), and values of H_{Therm} for respective measurements of H_{EREF}^{(k)}(I_{H})−H_{E}^{(k)}(I_{H}) and H_{EREF}^{(k)}(I_{L})−H_{E}^{(k)}(I_{L}). In one example implementation, I_{H}=100 μA=10² μA and I_{L}=10 nA=10⁻² μA, resulting in Δρ_{dB}=80 dB. Such a difference can be achieved at one particular value of TC, which is the satisfactory (or calibrated) value of TC. The satisfactory value of TC that is determined in such fashion can be stored in a register (referred to as TC or TC register, for the sake of nomenclature) within memory 180. After each channel is calibrated, N values of TC are stored in respective registers TC1, TC2, . . . and TCN within the memory 180. A determination of the satisfactory TC value can be referred to as a digital calibration of voltage Vₜₕₑᵣₘ (voltage 194).

Each one of the channels k (1, 2, . . . N) can have different TC values due to one or more factors. Such factors include mismatches in the thermometer, possibly arising from temperature differences in components within the thermometer circuitry 192b, the ADC 172 starting at a higher value than 0 at 0 V input, and the channels and/or slope differences of the input stages formed by the logarithmic current-to-voltage converter devices 142.

Using the analog calibration of V_{Therm} (which calibration is also referred to as an analog temperature calibration) based on the sensing circuitry 190 that is shown in FIG. 5B, for channel k, the expression of ρ_{dB} in units of dBμA (denoted by ρ_{dB}^{(k)}[dBμA]) can be derived in similar fashion as Eq. (11). Specifically, in a scenario where the logarithmic transimpedance amplifier device 110 uses the sensing circuitry 190 shown in FIG. 5B, the voltage 194 (e.g., V_{Therm} in FIG. 5B) can be expressed as, in units of LSB/V:

$${H}_{T h e r m} = {Γ}_{A D C} ( \frac{{k}_{B} ln ( A ) {R}_{T}}{q {R}_{P T}} ) T - {Γ}_{A D C} {V}_{B G} ( \frac{{R}_{T}}{{R}_{Z T}} ) ( 1 + \frac{T C}{M} - \frac{T {C}_{max} + 1}{2 M} ) \qquad ( 12 )$$

Here, the foregoing expression is a variation of Eq. (5), where again R_{T} is the thermometer load resistor (FIG. 5B) and R_{PT} is the resistor in the bandgap reference that sets the PTAT current I_{PT} (FIG. 5B), R_{ZT} is the resistor that sets the constant current I_{ZT}=V_{BG}/R_{ZT} (FIG. 5B), A denotes the area ratio of the bandgap (which ratio is 8 in the example in FIG. 5B)); and T is the temperature in Kelvin. From Eq. (12), H_{Therm} is negative at 0 K, in accordance with aspects discussed above. Accordingly, an offset [symbol] can be added in order for the output of the thermometer value to be zero at 0 K. In this way, as is described hereinbefore, for each channel k, H_{EREF}^{(k)}−H_{E}^{(k)} can be compensated with the absolute temperature T. Therefore, for compensation with the absolute temperature T,

$${H}_{T h e r m}^{( a b s )} = {Γ}_{A D C} ( \frac{{k}_{B} ln ( A ) {R}_{T}}{q {R}_{P T}} ) T - {Γ}_{A D C} {V}_{B G} ( \frac{{R}_{T}}{{R}_{Z T}} ) ( 1 + \frac{T C}{M} - \frac{T {C}_{max} + 1}{2 M} ) + {𝒪}^{′} \qquad ( 13 )$$

where at T=0 K,

$${H}_{T h e r m}^{( a b s )} ( 0 K ) = - {Γ}_{A D C} {V}_{B G} ( \frac{{R}_{T}}{{R}_{Z T}} ) ( 1 + \frac{T C}{M} - \frac{T {C}_{max} + 1}{2 M} ) + {𝒪}^{′} ≡ 0 \qquad ( 14 )$$

Again, in the idealized scenario where the ADC 172 is an ideal S-bit ADC ranging from 0 to V_{REF} (the voltage that drives the ADC 172),

$${Γ}_{A D C} = {2}^{S} / {V}_{REF} .$$

Thus, in case V_{REF}=2V_{BG}, the product Γ_{ADC}V_{BG}=2^{S-1}. and the expression for ρ_{dB}^{(k)}[dBμA], for analog temperature calibration, can be obtained following the steps involved in the derivation of Eqs. (8)-(10) but using the appropriate expression for [symbol] resulting from Eq. (14). Hence, ρ_{dB}^{(k)}[dBμA] can be expressed as:

$${ρ}_{d B}^{( k )} [ dB μA ] = \frac{20 ln ( A ) {R}_{T}}{ln ( 10 ) {R}_{P T}} ( \frac{{H}_{E R E F}^{( k )} - {H}_{E}^{( k )}}{{H}_{T h e r m} + \frac{{2}^{S - 1} {R}_{T}}{{R}_{Z T}} ( 1 + \frac{2 \cdot TC - ( T {C}_{max} + 1 )}{2 \cdot M} )} ) \qquad ( 15 )$$

with TCₘₐₓ being the maximum value of the (decimal) TC register content, and the other parameters being the same as those defined above in connection with Eq. (11), but pertaining to the sensing circuitry 190 in FIG. 5B. For example, for a 5-bit IDAC, TCₘₐₓ=31 and the adjustment factor (or calibration amount) is equal to zero for TC=16, thus permitting both positive adjustment factors (for TC>16) and negative adjustment factors (for TC<16). In Eq. (12), M is the scaling parameter used in FIG. 3.

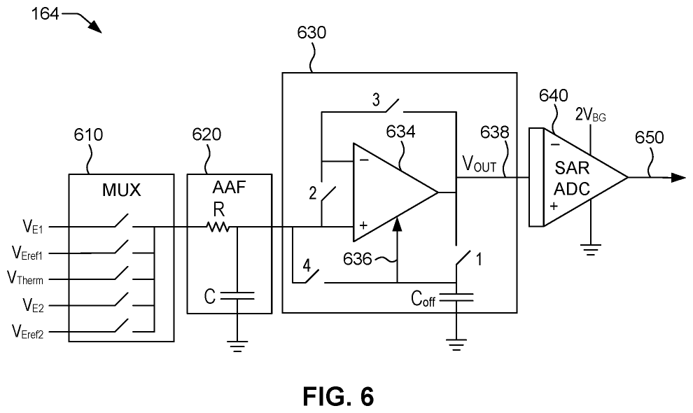

After calibration of TC, IREF, IPT, and ICT, the processor 130 can determine ρ_{dB}[dBμA] for each channel k (1, 2, . . . N), at temperature T, according to one of Eq. (11) or Eq. (15) above, with ΔH^{(k)}=H_{REF}^{(k)}−H_{E}^{k}). It is noted that calibration of the foregoing values or registers can be performed in any order. In one example sequence, TC is calibrated before, then I_{REF} is calibrated, which calibration precedes I_{PT}, which in turn precedes the calibration of PCT. Simply as an illustration, FIG. 7 presents observed data for ρ_{dB}^{(k)}[dBμA] as a function of input current in a two-channel (N=2) device 100 in accordance with aspects of this disclosure. Plot 700 and plot 750 present observed data for ρ_{dB}^{(k)}[dBμA] in a first channel (k=1) and a second channel (k=2), respectively. FIG. 7 also presents logarithmic conformance derived from the observed data. Logarithmic conformance refers to the degree of conformance of the difference of readout values V_{E} and V_{EREF} with Eq. (2).

In addition, or in some cases, the processor 130 can implement one or several adjustments (or compensations) before a determination of ρ_{dB}^{(k)}[dBμA], and thus an input current. An example adjustment is subtraction of a defined current from an initial current calculated by the processor 130 using ρ_{dB}^{(k)}[dBμA]. The defined current represents a residual leakage current in the logarithmic transimpedance amplifier device 110 as manufactured. The residual leakage current depends on temperature, approximately doubling every 15° C. change in temperature. Thus, the defined current that is subtracted also depends on temperature and can be referred to as leakage equivalent current. The leakage equivalent current uses the calibrated thermometer reading for compensation. That is, the leakage equivalent current can be defined as a function of a calibrated thermometer reading. The leakage equivalent current can be determined by performing measurements on the device 100, and determining a predictive model of leakage current as a function of temperature. After the predictive model is determined, the calibrated thermometer reading is input into the model and a particular value of the leakage equivalent current can be obtained. Values of the leakage equivalent current are in the order of about 9 μA. As a result of subtracting the leakage equivalent current, accuracy of a determination of magnitudes of input currents 102(1)-102(N) can be improved for low input currents at higher temperatures, without degrading accuracy of such a determination at lower temperatures.

Another example adjustment is a correction to logarithmic conformance of V_{E}−V_{EREF} as a function of the ratio I_{NP} and I_{REF}. In one implementation, the processor 130 can apply a second-order polynomial correction with the center of the parabola at the nominal reference current (e.g., 1 μA). The disclosure is not limited in that respect, and other corrections can be defined in terms of other functions of input current. An example of those other functions is a fourth-order polynomial correction centered at the nominal reference current. Other univariate polynomial functions of higher order can be used.

Yet another example adjustment is a compensation for emitter resistance of the logging transistor Qlog1 (FIG. 2). Such a compensation can account for an additional voltage drop for V_{EREF}−V_{E} (see FIG. 2) at input currents having a magnitude near the upper end of the dynamic range of expected dynamic range of the logarithmic transimpedance amplifier device 110. As mentioned, such a dynamic range can extend from about 1 μA to about 10 mA. Thus, compensation for emitter resistance can be implemented for input current having a magnitude in a range from about 8 mA to about 10 mA. For each channel k, the processor 130 can implement such a compensation by iteratively subtracting a correction value from ΔH^{(k)}=H_{EREF}^{(k)}−H_{E}^{(k)} until a desired or otherwise satisfactory value of input current is attained. At a particular iteration, a correction value can be determined by multiplying a measured input current by an emitter-resistance equivalent value representing the systematic emitter resistance of Qlog1 (FIG. 2) and then multiplying a resulting voltage by the gain ΓADC of the ADC 172, which results in a second voltage representative of a corrected value of ΔH^{(k)}=H_{EREF}^{(k)}−H_{E}^{(k)}. At a subsequent iteration, the processor 130 can determine a next measured input current using Eq. (11) (or Eq. (15) in cases of analog calibration of V_{Therm}) with the corrected value of ΔH^{(k)}. Using the next measured input current, processor 130 can determine a next correction value by multiplying the next measured input current by a next emitter-resistance equivalent value representing the systematic emitter resistance of Qlog1 (FIG. 2) and then multiplying a next resulting voltage by the gain Γ_{ADC}, which results in a second next voltage representative of a next corrected value of ΔH^{(k)}. The processor 130 can then determine a second next measured input current using Eq. (11) with the next corrected value of ΔH^{(k)}. Such an iterative process can continue until the measured input current satisfies a termination criterion, such as a desired accuracy.

Other example adjustments include any additional compensation in ρ_{dB}^{(k)}[dBμA] based on the calibrated thermometer reading. This could potentially lower the error in the −40° C. logarithmic conformance curve. Without intending to be bound by theory and/or phenomenology, errors in the −40° C. logarithmic conformance curve may arise from non-linearities in the voltage 194 (which is an analog thermometer signal) versus temperature. Thus, such other example adjustments can include fitting the temperature dependence of V_{Therm} (the voltage 194) and, in some cases, updating such a fitting according to a schedule or periodically.

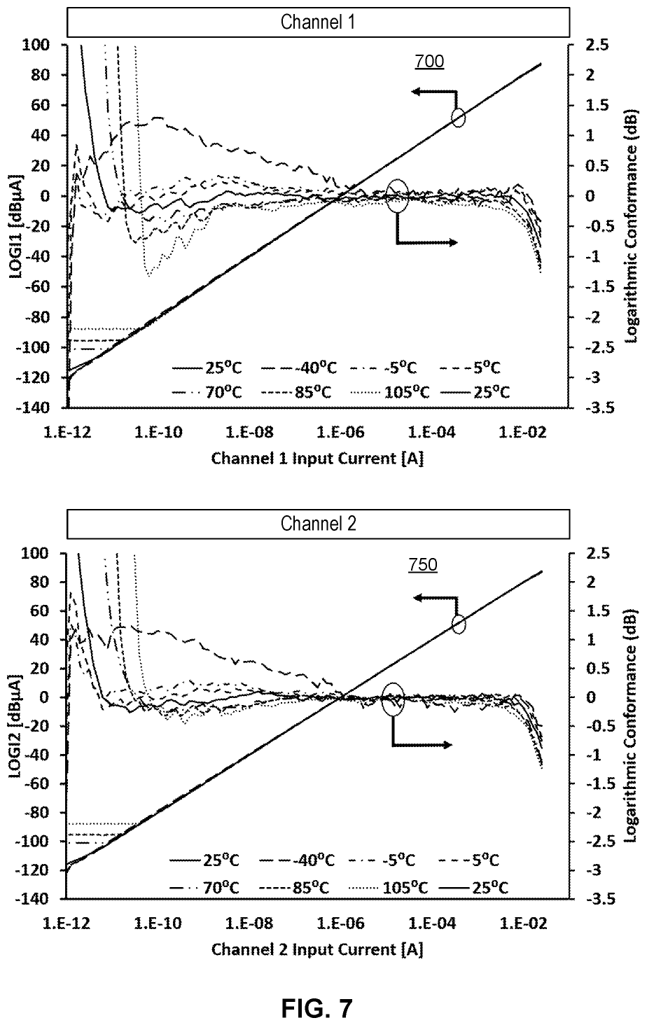

FIG. 8 is a plot 800 of logarithmic conformance as a function of input current in a channel of a two-channel (N=2) device 100 (FIG. 1) in accordance with aspects of this disclosure. The logarithmic conformance is determined from observed data (see FIG. 7, for example) at a temperature of 70° C. and according to some of the adjustments described hereinbefore. Logarithmic conformance as a function of input current, without adjustments (labeled “Uncompensated”) also is shown. The logarithmic conformance after emitter resistance (Re), curvature, and leakage compensations are incorporated provides a smaller conformance error over a wider input dynamic range compared to the Uncompensated results.

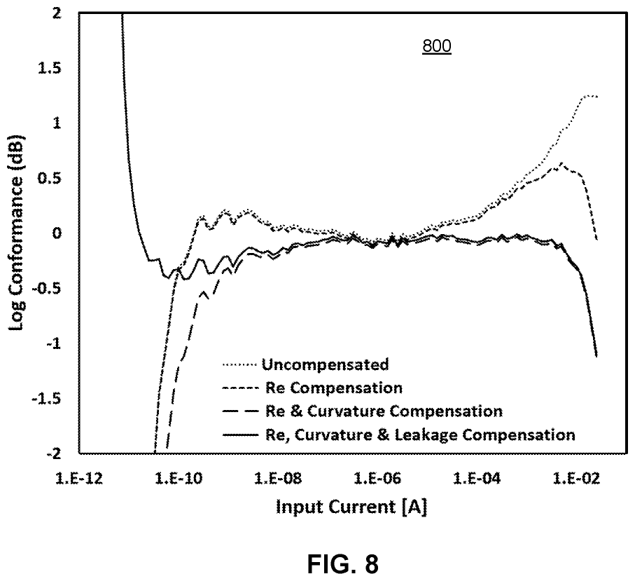

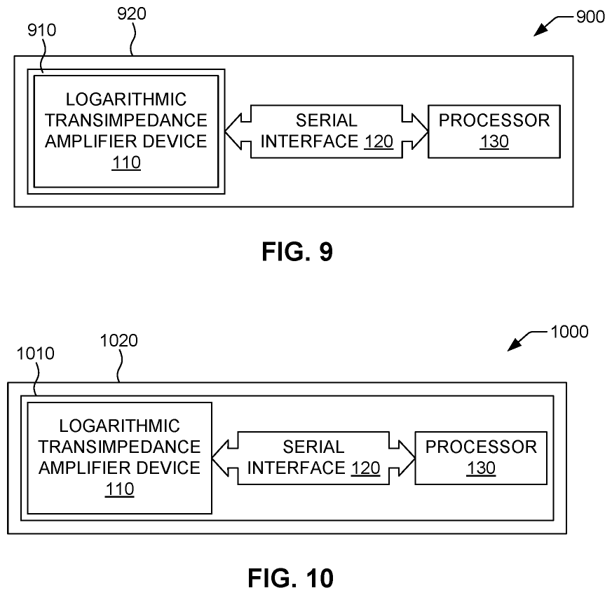

The device 100 (FIG. 1) can be utilized in various optical power detection apparatuses, such as optical modulators, light detection and ranging (LiDAR) systems, and the like. To that end, the device 100 can be packaged in several ways. In one example, as is shown in FIG. 9, the logarithmic transimpedance amplifier device 110 can be packaged on a single die 910, using to wafer level chip scale package (WLCSP) techniques. The die 910, the serial interface 120, and the processor 130 can be assembled on printed circuit board (PCB) 920. Such a packaging results in an example device 900 that operates in accordance with aspects of this disclosure. In another example, as is shown in FIG. 10, the logarithmic transimpedance amplifier device 110, the serial interface 120, and the processor 130 are packaged on a single die 1010, using WLCSP techniques. The single die 1010 can be assembled on a PCB 1020. Such a packaging results in an example device 1000 that operates in accordance with aspects of this disclosure.

Other configurations of the logarithmic transimpedance amplifier device 100 also are contemplated. In some example configurations, the generation of the digital signals used in the determination of the logarithm of an input current can be performed outside the logarithmic transimpedance amplifier device 110. In such example configurations, the signal processing circuitry 164 that generates the digital signals can be assembled off-chip. In addition, or in some cases, a replica of the signal processing circuitry 164 also can be retained within the logarithmic transimpedance amplifier device 110 for calibration purposes. Further, calibration of the analog thermometer signal (Vₜₕₑᵣₘ) also can be used.

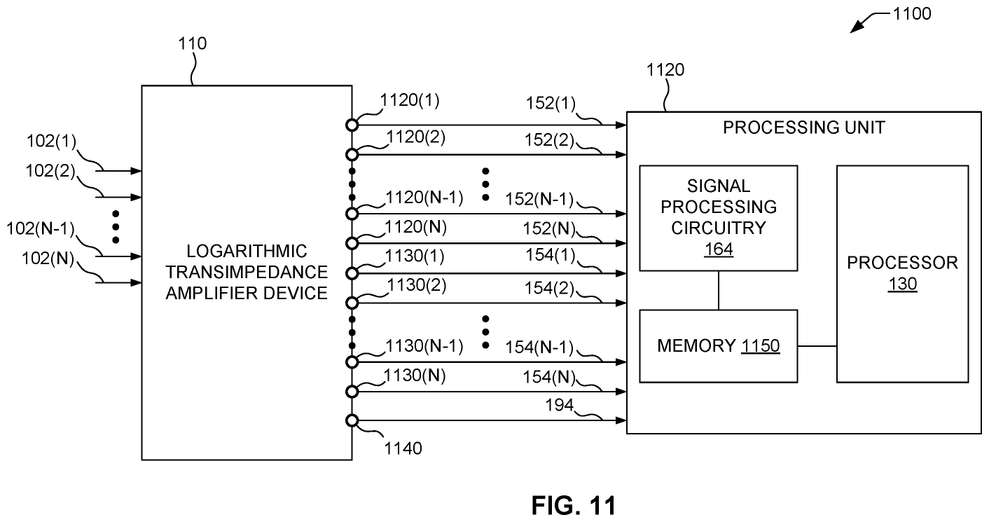

As an illustration, FIG. 11 is a schematic block diagram of an example of a device 1100 to determine a logarithm of an input current to a logarithmic transimpedance amplifier device regardless of temperature, where the current is responsive to an optical input power, in accordance with one or more aspects of this disclosure. The example device 1100 includes the logarithmic transimpedance amplifier device 110 and a processing unit 1120 functionally coupled therewith. The logarithmic transimpedance amplifier device 110 has the same functional elements that are shown in FIG. 1 and associated functionality described in this disclosure.

In addition, as is shown in FIG. 11, the amplifier device 110 included in the device 1100 has multiple pins (represented by open circles) that permit outputting analog voltage signals generated by the logarithmic current-to-voltage converter devices 142 and the sensing circuitry 190 present in the amplifier device 110. As is described herein, in some implementations of the amplifier device 110 included in the device 1100, the sensing circuitry 190 can be configured according to one of the circuitry shown in FIG. 5A or the circuitry shown in FIG. 5B. Because the processing unit 1120 can be assembled independently of the amplifier device 110, the sensing circuitry 190 according to the circuitry shown in FIG. 5B is used in some cases in order to permit analog calibration of the voltage 194 in the factory, during or after fabrication of the amplifier device 110. By relying on analog calibration, the amplifier device 110 included in the device 1100 can be temperature calibration without knowledge of the ADC gain of the ADC 172 that is present in the signal processing circuitry 164 within processing unit 1120.

The multiple pins that permit outputting voltage signals include a first pin 1120(1), a second pin 1120(2), up to a N−1-th pin 1120(N−1) and a pin 1120(N) that respectively output the voltages 152(1)-152(N). The multiple pins also include a first pin 1130(1), a second pin 1130(2), up to an N−1-th pin 1130(N−1) and an N-th pin 1130(N) that respectively output the voltages 154(1)-154(N). The multiple pins also include a pin 1140 that outputs the voltage 194. The multiple pins that is, pins 1120(1)-1120(N), pins 1130(1)-1130(N), and pin 1140-constitute a pinout assembly that is part of an analog interface (not depicted in FIG. 11) that couples, at least partially, the logarithmic transimpedance amplifier device 110 with the processing unit 1120. The analog interface also includes multiple conductive pads, traces, other types of conductive wires, or a combination thereof, that permit transporting the analog signals that are output via the pins 1120(1)-1120(N), pins 1130(1)-1130(N), and pin 1140. The analog interface also includes another pinout assembly and/or a peripheral adapter assembled at the processing unit 1120 that also permits coupling, at least partially, the processing unit 1120 with the logarithmic transimpedance amplifier device 110.

The processing unit 1120 can receive the voltages 152(1)-152(N), voltages 154(1)-154(N), and voltage 194, and can process those voltages to generate respective digital signals. To that end, the processing unit 1120 includes the signal processing circuitry 164 described herein. The signal processing circuitry 164 can retain the respective digital signals as digital data in one or more memory devices 1150 (referred to as memory 1150). The memory 1150 can be embodied in or can include the memory 180 described herein.

The processing unit 1120 also includes the processor 130 described herein. The processor 130 can read digital data corresponding to the digital signals generated by the signal processing circuitry 164, and for each channel k (1, 2, . . . N), the processor 130 can then generate a logarithmic ratio of the input current 102(k) and a reference current for the channel k, in accordance with aspects described herein. The processor 130 also can implement the various adjustments (or compensations) described herein, to improve the determination of input currents.

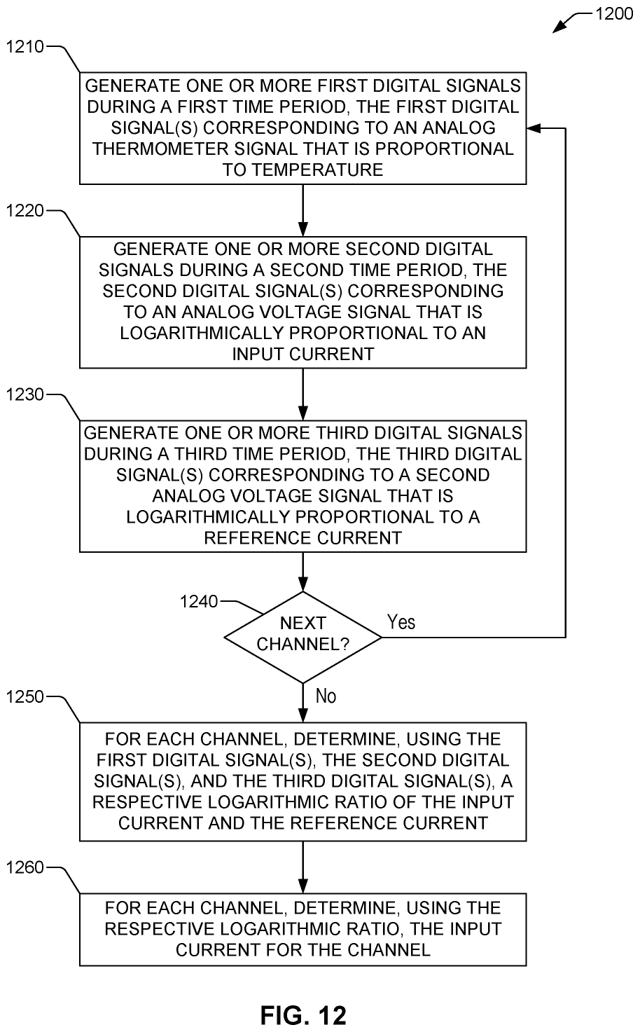

Aspects of the methods that can be implemented in accordance with this disclosure can be better appreciated with reference to FIGS. 12-14. For purposes of simplicity of explanation, the example methods illustrated in FIGS. 12-14 are presented and described as a series of acts or operations. Such example methods, individually or in combination, are not limited by the order of the acts, as some acts may occur in different orders and/or concurrently with other acts from that shown in each of FIGS. 12-14 and described herein. In some cases, one or more methods in accordance with aspects of this disclosure can alternatively be represented as a series of interrelated states or events, such as in a state diagram depicting a state machine. In addition, or in other cases, interaction diagram(s) (or process flow(s)) may represent methods in accordance with aspects of this disclosure when different entities enact different portions of the methods. Not all illustrated acts (or blocks representing the acts) may be required to implement a described example method in accordance with this disclosure. Further, two or more of the disclosed example methods can be implemented in combination with each other, to accomplish one or more functionalities described herein.

FIG. 12 is a flowchart of an example method 1200 for determining a logarithm of an input current to a logarithmic transimpedance amplifier device at a particular temperature, in accordance with one or more aspects of this disclosure. As mentioned, the input current can be responsive to an optical input power. The example method 1200 can be implemented by a device or apparatus that combines the logarithmic transimpedance amplifier device and one or more processors, in accordance with aspects described herein. The processor(s) being functionally coupled with the logarithmic transimpedance amplifier device via a serial interface (e.g., serial interface 120 (FIG. 1). The device or apparatus that implements the example method 1200 can include the device 100 (FIG. 1), for example. As such, the logarithmic transimpedance amplifier device can be the logarithmic transimpedance amplifier device 110 (FIG. 1) for example.

At block 1210, the logarithmic transimpedance amplifier device can generate one or more first digital signals during a first time interval. Each of the one or more first digital signals corresponds to an analog thermometer signal (e.g., voltage 194 (FIG. 1)) that is proportional to a temperature of the logarithmic transimpedance amplifier device. Block 1210 is implemented in analog domain.

At block 1220, the logarithmic transimpedance amplifier device can generate one or more second digital signals during a second time interval. Each of the second digital signals corresponds to an analog voltage signal that is logarithmically proportional to the input current received at the logarithmic transimpedance amplifier device. The input current is responsive to input optical power and, as is described herein, can have a substantial dynamic range. Block 1220 is implemented in analog domain.

At block 1230, the logarithmic transimpedance amplifier device can generate one or more third digital signals during a third time interval. Each of the third digital signals corresponds to a second analog voltage signal that is logarithmically proportional to a reference current generated by the logarithmic transimpedance amplifier device. The logarithmic transimpedance amplifier device includes a current generator device (e.g., one of current generator devices 146 (FIG. 1)) that generates the reference current, in accordance with aspects described herein. Block 1230 is implemented in analog domain.

As is described herein, generating the first digital signal(s), the second digital signal(s), and the third digital signal(s) includes sequentially sampling the analog thermometer signal, the analog voltage signal, and the second analog voltage signal. Thus, the first time interval, the second time interval, and the third time interval are sequentially ordered according to a defined sequence. Such intervals also are pairwise consecutive; that is, for all possible pairs of time intervals, a particular one of the time intervals in the pair is consecutive to a second particular one of the time intervals in the pair. To sample such analog signals, the logarithmic transimpedance amplifier device can include the signal processing circuitry 164 (FIG. 1).

Generating the first digital signal(s) includes selecting, consistent with the defined sequence, the analog thermometer signal and processing the analog thermometer signal via, for example, the signal processing circuitry 164. The analog thermometer signal can be selected via, for example, a multiplexer included in the signal processing circuitry 164. Processing the analog thermometer signal includes filtering and amplifying the analog thermometer signal, resulting in a processed analog thermometer signal. Generating the first digital signal(s) also includes sampling the processed analog thermometer signal using an ADC device that is included in the signal processing circuitry 164. The sampling results in the first digital signal(s). Further, determining the second digital signal(s) also includes selecting, consistent with the defined sequence, the analog voltage signal and processing the analog voltage signal via, for example, the signal processing circuitry 164. The analog voltage signal can be selected via, for example, the multiplexer. Processing the analog voltage signal includes filtering and amplifying the analog voltage signal, resulting in a processed analog voltage signal. Generating the second digital signal(s) also includes sampling the processed analog voltage signal using the ADC device. The sampling results in the second digital signal(s). Furthermore, determining the third digital signal(s) also includes selecting, consistent with the defined sequence, the second analog voltage signal and processing the second analog voltage signal via, for example, the signal processing circuitry 164. The analog voltage signal can be selected via, for example, the multiplexer. Processing the second analog voltage signal includes filtering and amplifying the analog thermometer signal, resulting in a processed second analog voltage signal. Generating the third digital signal(s) also includes sampling the processed second analog voltage signal using the ADC device. The sampling results in the third digital signal(s).

In cases where the logarithmic transimpedance amplifier device includes multiple channels, the example process method 1200 includes block 1240. At such a block, it is determined if additional digital signals are to be generated for a next channel. Such a determination can be based on control signaling (e.g., control bits) received from a processor functionally coupled with the logarithmic transimpedance amplifier device. For example, control signaling indicative of selection of analog signals from the next channel causes an affirmative determination at block 1240. In the alternative, absence of such control signaling causes a negative determination at block 1240.

A positive determination at block 1240 (“Yes” branch) results in the flow of example method 1200 returning to block 1210, where first, second, and third digital signals are generated for another channel of the logarithmic transimpedance amplifier device in response to additional implementation of blocks 1210-1230. As is described herein, that other channel receives another input current and generates a reference current that is substantially the same as the reference current of other channel(s) in the logarithmic transimpedance amplifier device.

A negative determination at block 1240 (“No” branch) results in the flow of example method 1200 continuing to block 1250 where, for each channel (or, in some implementations, at least one channel) of the logarithmic transimpedance amplifier device, the processor(s) can determine a respective logarithmic ratio of the input current and the reference current for the channel being processed, using the one or more first digital signals, the one or more second digital signals, and the one or more third digital signals. By generating such a ratio, the processor(s) can determine input currents corresponding to respective channels of the logarithmic transimpedance amplifier device. Indeed, as is shown at block 1260, for each channel (or in some implementations, at least one channel) of the logarithmic transimpedance amplifier device, the processor(s) can determine, using the respective logarithmic ratio, the input current for the channel being processed.

More specifically, the processor(s) can determine such a logarithmic ratio individually or in combination, by applying Eq. (11) or Eq. (15). Hence, determining, using the one or more first digital signals, the one or more second digital signals, and the one or more third digital signals, the logarithmic ratio of the input current and the reference current can include adding a calibration value to a particular one of the first digital signal(s), resulting in a calibrated digital signal, and determining, based on the calibrated digital signal, a temperature dependent correction to a difference of a particular one of the second digital signal(s) and a particular one of the third digital signal(s).

In cases where the logarithmic transimpedance amplifier device includes multiple channels, the generation of the first digital signal need not be implemented in each channel iteration. That is, in some cases, the generation of the first digital signal corresponding to the analog thermometer signals can be implemented after a particular number of channel iterations have been implemented. Thus, the generation of the first digital signal can be interleaved with the generation of multiple second digital signals and multiple third signals for a subset of the multiple channels, where the subset itself has multiple channels.

In cases where the logarithmic transimpedance amplifier device has or is otherwise configured to operate with a single channel, the example method 1200 can exclude or can bypass block 1240.

Although not illustrated in FIG. 12, in some implementations, the example method 1200 includes applying, for each channel (or, in some cases, at least one channel), an adjustment to (i) an initial input current obtained for the channel from the logarithmic ratio of the input current and the reference current. In addition, or in other implementations, the example method 1200 includes applying, for each channel (or, in some cases, at least one channel), an adjustment to one or more of (a) the first digital signal(s), (b) the second digital signal(s), or (c) the third digital signal(s) before the determination of the logarithmic ratio of the input current and the reference current for the channel. The processor(s), individually or in combination, can apply an adjustment or a combination of adjustments.

An example of an adjustment (or compensation) that can be applied includes a subtraction of a defined current from an initial input current obtained from such a logarithmic ratio. The defined current represents a residual leakage current in the logarithmic transimpedance amplifier device as manufactured. Another example of an adjustment (or compensation) that can be applied includes an emitter compensation at high input currents. A high input current is a current that exceeds a threshold amount. Accordingly, applying such an adjustment for emitter compensation includes, in some cases, determining an input current based on the logarithmic ratio of the input current and the reference current, and determining that the input current exceeds the threshold amount. Applying the adjustment also includes determining a voltage offset by multiplying the input current by an emitter-resistance equivalent value, and subtracting the voltage offset from the second analog voltage signal.

The application of one or more adjustments (or compensations) can provide a more accurate value of the input current. Notably, the application of such compensation(s) is unavailable in existing technologies that determine temperature compensation in the analog domain. Accordingly, the technologies in accordance with aspects of this disclosure clearly provide an improvement over existing technology.

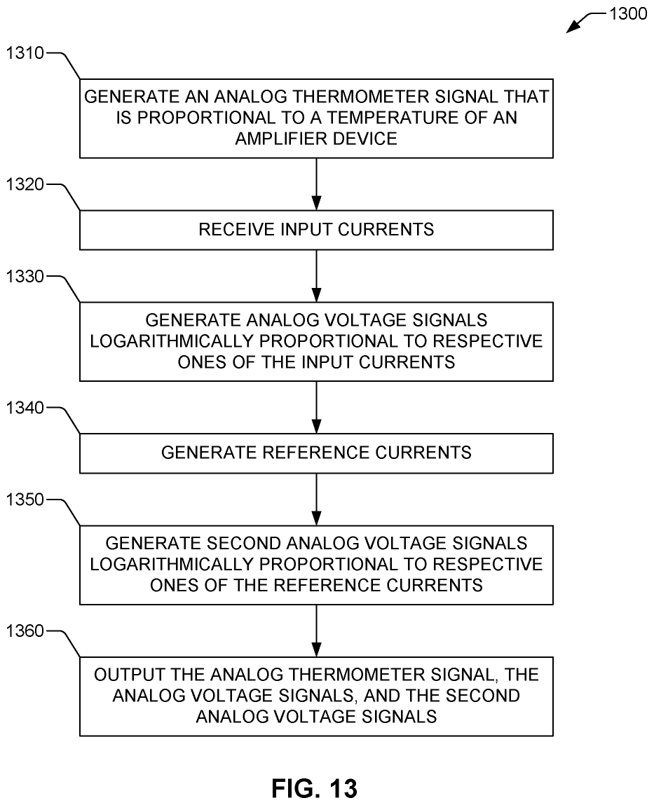

FIG. 13 is a flowchart of an example method 1300 for supplying analog signals that can be used to determine a logarithm of an input current to a logarithmic transimpedance amplifier device at a particular temperature, in accordance with one or more aspects of this disclosure. As mentioned, the input current can be responsive to an optical input power. The example method 1300 can be implemented by a device or apparatus that includes the logarithmic transimpedance amplifier device in accordance with aspects described herein. The processor(s) being functionally coupled with the logarithmic transimpedance amplifier device via a serial interface (e.g., serial interface 120 (FIG. 1). In some cases, the device or apparatus that implements the example method 1300 includes the logarithmic transimpedance amplifier device 110 (FIG. 1) described herein.

At block 1310, a device can generate an analog thermometer signal that is proportional to a temperature of a logarithmic transimpedance amplifier device that is included in the device. The logarithmic transimpedance amplifier device can generate the analog thermometer signal. In some cases, the logarithmic transimpedance amplifier device is the logarithmic transimpedance amplifier device 110 (FIG. 1) and generates the analog thermometer signal via circuitry 190 in accordance with aspects described herein.

At block 1320, the device can receive input currents. For example, the input currents can be the input currents 102(k), with k=1, 2, . . . N, where N≥1. In some cases, N=2, as is described herein.

At block 1330, the device can generate, via the logarithmic transimpedance amplifier device, analog voltage signals logarithmically proportional to respective ones of the input currents. In cases where the logarithmic transimpedance amplifier device is the logarithmic transimpedance amplifier device 110 (FIG. 1), the logarithmic current-to-voltage converter devices 142 can generate the analog voltage signals (e.g., signals 152(k), with k=1, 2, . . . N, where N≥1).

At block 1340, the device can generate reference currents. For example, the reference currents can be the reference currents 148(k), with k=1, 2, . . . N, where N≥1. In cases where the logarithmic transimpedance amplifier device is the logarithmic transimpedance amplifier device 110 (FIG. 1), the current generator devices 146 can generate the reference currents.

At block 1350, the device can generate, via the logarithmic transimpedance amplifier device, second analog voltage signals logarithmically proportional to respective ones of the reference currents. In cases where the logarithmic transimpedance amplifier device is the logarithmic transimpedance amplifier device 110 (FIG. 1), the logarithmic current-to-voltage converter devices 142 can generate the second analog voltage signals (e.g., signals 154(k), with k=1, 2, . . . N, where N≥1).

At block 1360, the device can output, via the logarithmic transimpedance amplifier device, the analog thermometer signal, the analog voltage signals, and the second analog voltage signals. To that end, as is described herein, the logarithmic transimpedance amplifier device includes a portion of an analog interface, where the analog interface is configured to output the analog thermometer signal, the analog voltage signal, and the second analog voltage signals. The analog interface also is configured to transport such signals to another device or apparatus that is external to the logarithmic transimpedance amplifier device. To that point, the analog interface includes multiple conductive pads, traces, other types of conductive wires, or a combination thereof. The analog interface includes a pinout assembly, where a first pin in the pinout assembly (e.g., the pinout assembly illustrated in FIG. 11) is configured to output the analog voltage signal; a second pin in the pinout assembly is configured to output the second analog voltage signal; and a third pin in the pinout assembly is configured to output the analog thermometer signal.

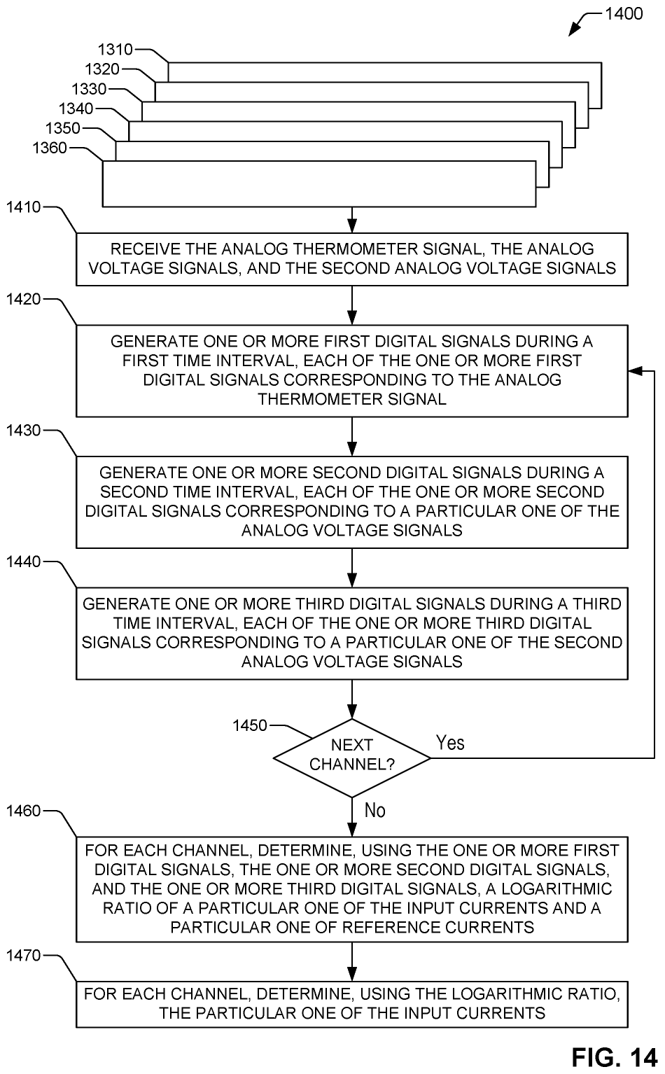

As is described herein, with reference to FIG. 11, for example, analog signals output by a logarithmic transimpedance amplifier device of this disclosure can be used by a processing unit to determine a logarithm of an input current to the logarithmic transimpedance amplifier device at a particular temperature, in accordance with one or more aspects of this disclosure. Hence, the example method 1300 can be combined with various other blocks to form the example method 1400 shown in FIG. 14. In the example method 1400, the logarithmic transimpedance amplifier device can implement the portion corresponding to the example method 1300 and the processing unit can implement blocks 1410-1460. The processing unit is or includes the processing unit 1120 (FIG. 11) in some cases.

At block 1410, the processing unit can receive the analog thermometer signal, the analog voltages signal, and the second analog voltage signals. Those signals result from the implementation of the example method 1300. To receive such signals, the processing unit is functionally coupled with the logarithmic transimpedance amplifier device via the analog interface described hereinbefore in connection with block 1360 (and other passages of this disclosure). As mentioned, the analog interface includes a pinout assembly and/or a peripheral adapter assembled at the processing unit.

At block 1420, the processing unit can generate one or more first digital signals during a first time interval. Each of the one or more first digital signals corresponds to the analog thermometer signal (e.g., voltage 194 (FIG. 1)). Block 1420 is implemented in analog domain. In some cases, the processing unit includes the signal processing circuitry 164 described herein. Hence, the processing unit generates the one or more first digital signals via the signal processing circuitry 164.

At block 1430, the processing unit can generate one or more second digital signals during a second time interval. Each of the one or more second digital signals corresponds to a particular one of the analog voltage signals.

At block 1440, the processing unit can generate one or more third digital signals during a third time interval. Each of the one or more third digital signals corresponds to a particular one of the second analog voltage signals. Block 1440 is implemented in analog domain.

As is described herein, generating the first digital signal(s), the second digital signal(s), and the third digital signal(s) includes sequentially sampling the analog thermometer signal, the analog voltage signals, and the second analog voltage signals. Thus, the first time interval, the second time interval, and the third time interval are sequentially ordered according to a defined sequence. Such intervals also are pairwise consecutive; that is, for all possible pairs of time intervals, a particular one of the time intervals in the pair is consecutive to a second particular one of the time intervals in the pair. To sample such analog signals, the processing unit includes the signal processing circuitry 164 (FIG. 1).

Generating the first digital signal(s) includes selecting, consistent with the defined sequence, the analog thermometer signal and processing the analog thermometer signal via, for example, the signal processing circuitry 164. The analog thermometer signal can be selected via, for example, a multiplexer included in the signal processing circuitry 164. Processing the analog thermometer signal includes filtering and amplifying the analog thermometer signal, resulting in a processed analog thermometer signal. Generating the first digital signal(s) also includes sampling the processed analog thermometer signal using an ADC device that is included in the signal processing circuitry 164. The sampling results in the first digital signal(s). Further, generating the second digital signal(s) also includes selecting, consistent with the defined sequence, the analog voltage signal and processing the analog voltage signal via, for example, the signal processing circuitry 164. The analog voltage signal can be selected via, for example, the multiplexer. Processing the analog voltage signal includes filtering and amplifying the analog voltage signal, resulting in a processed analog voltage signal. Generating the second digital signal(s) also includes sampling the processed analog voltage signal using the ADC device. The sampling results in the second digital signal(s). Furthermore, generating the third digital signal(s) also includes selecting, consistent with the defined sequence, the second analog voltage signal and processing the second analog voltage signal via, for example, the signal processing circuitry 164. The analog voltage signal can be selected via, for example, the multiplexer. Processing the second analog voltage signal includes filtering and amplifying the analog thermometer signal, resulting in a processed second analog voltage signal. Generating the third digital signal(s) also includes sampling the processed second analog voltage signal using the ADC device. The sampling results in the third digital signal(s).

In cases where the logarithmic transimpedance amplifier device includes multiple channels (that is, N in FIG. 1 is greater than unity, for example), the example method 1400 includes block 1450. At such a block, the processing unit can determine if additional digital signals are to be generated for a next channel. Such a determination can be based on control signaling (e.g., control bits) retained within a memory device (e.g., a register or another type of memory device) that is accessible to the processing unit. For example, such the memory device can be integrated into the processing unit—e.g., the memory device can be or can include the memory 1150 (FIG. 11). For example, control signaling indicative of selection of analog signals from the next channel causes an affirmative determination at block 1450. In the alternative, absence of such control signaling causes a negative determination at block 1450.

A positive determination at block 1450 (“Yes” branch) results in the flow of the example method 1400 returning to block 1420, where first digital signal(s), second digital signal(s), and third digital signal(s) can be generated for another channel of the logarithmic transimpedance amplifier device in response to additional implementation of blocks 1420-1440.

A negative determination at block 1450 (“No” branch) results in the flow of example method 1400 continuing to block 1460 where, for each channel (or, in some implementations, at least one channel) of the logarithmic transimpedance amplifier device, the processing unit can determine a logarithmic ratio of a particular one of the input currents and a particular one of the reference currents using the one or more first digital signals, the one or more second digital signals, and the one or more third digital signals that have been generated for the channel being processed. Here, the particular one of the input currents corresponds to the channel being processed, and the particular one of the reference currents also corresponds to the channel being processed. By generating such a ratio for each channel, the processing unit can determine input currents corresponding to respective channels of the logarithmic transimpedance amplifier device. Indeed, as is shown at block 1470, for each channel (or in some implementations, at least one channel) of the logarithmic transimpedance amplifier device, the processing unit can determine, using the logarithmic ratio, the particular one of the input currents—that is, the input current for the channel being processed.

More specifically, the processing unit can determine such a logarithmic ratio by applying Eq. (11) or Eq. (15). Hence, determining, using the one or more first digital signals, the one or more second digital signals, and the one or more third digital signals, the logarithmic ratio of the input current and the reference current can include adding a calibration value to a particular one of the first digital signal(s), resulting in a calibrated digital signal, and determining, based on the calibrated digital signal, a temperature dependent correction to a difference of a particular one of the second digital signal(s) and a particular one of the third digital signal(s).

In some cases, in accordance with aspects described herein, the one or more first digital signals include multiple first digital signals, the one or more second digital signals include multiple second digital signals, and the one or more third digital signals include multiple third digital signals. While not shown in FIG. 14, the example method 1400 can then include determining an average of the multiple first digital signals, resulting in a first average value; determining an average of the multiple second digital signals, resulting in a second average value; determining an average of the multiple third digital signals, resulting in a third average value. Thus, as part of implementing block 1460, for a particular channel, the processing unit can determine, using the first average value, the second average value, and the third average value, the logarithmic ratio of the input current and the reference current for the channel.

In cases where the logarithmic transimpedance amplifier device that implements blocks 1310-1360 includes multiple channels, the generation of the first digital signal(s) need not be implemented in each channel iteration. That is, in some cases, the generation of the first digital signal(s) corresponding to the analog thermometer signals can be implemented after a particular number of channel iterations have been implemented. Thus, the generation of the first digital signal(s) can be interleaved with the generation of multiple second digital signals and multiple third signals for a subset of the multiple channels, where the subset itself has multiple channels. In cases where the logarithmic transimpedance amplifier device has or is otherwise configured to operate with a single channel, the example method 1400 can exclude or can bypass block 1450.

Although not illustrated in FIG. 14, in some implementations, the example method 1400 includes applying, for each channel (or, in some cases, at least one channel), an adjustment to (i) an initial input current obtained for the channel from the logarithmic ratio of an input current and a reference current for the channel. In addition, or in other implementations, the example method 1400 includes applying, for each channel (or, in some cases, at least one channel), an adjustment to one or more of (a) the first digital signal(s), (b) the second digital signal(s), or (c) the third digital signal(s) before the determination of the logarithmic ratio of the input current and the reference current for the channel. The processing unit (via the processor 130, for example) can apply an adjustment or a combination of adjustments.

An example of an adjustment (or compensation) that can be applied includes a subtraction of a defined current from an initial input current from such a logarithmic ratio. The defined current represents a residual leakage current in the logarithmic transimpedance amplifier device as manufactured. Another example of an adjustment (or compensation) that can be applied includes an emitter compensation at high input currents. A high input current is a current that exceeds a threshold amount. Accordingly, applying such an adjustment for emitter compensation includes, in some cases, determining an input current based on the logarithmic ratio of the input current and the reference current, and determining that the input current exceeds the threshold amount. Applying the adjustment also includes determining a voltage offset by multiplying the input current by an emitter-resistance equivalent value, and subtracting the voltage offset from the second analog voltage signal.

As mentioned, the application of one or more adjustments (or compensations) can provide a more accurate value of the input current. Notably, the application of such compensation(s) is unavailable in existing technologies that determine temperature compensation in the analog domain. Accordingly, the technologies in accordance with aspects of this disclosure clearly provide an improvement over existing technology.

Numerous example embodiments emerge from the foregoing detailed description and annexed drawings. Such example embodiments include the following:

Example 1. A device, comprising: a logarithmic transimpedance amplifier device configured to: generate one or more first digital signals during a first time interval, each of the one or more first digital signals corresponding to an analog thermometer signal that is proportional to a temperature of the logarithmic transimpedance amplifier device; generate one or more second digital signals during a second time interval, each of the one or more second digital signals corresponding to an analog voltage signal that is logarithmically proportional to an input current received at the logarithmic transimpedance amplifier device; and generate one or more third digital signals during a third time interval, each of the one or more third digital signals corresponding to a second analog voltage signal that is logarithmically proportional to a reference current generated by the logarithmic transimpedance amplifier device; and a processor functionally coupled with the logarithmic transimpedance amplifier device, the processor being configured to determine, using the one or more first digital signals, the one or more second digital signals, and the one or more third digital signals, a logarithmic ratio of the input current and the reference current.

Example 2. The device of example 1, wherein the one or more first digital signals comprise multiple first digital signals, the one or more second digital signals comprise multiple second digital signals, and the one or more third digital signals comprises multiple third digital signals; and wherein the processor is further configured to: determine an average of the multiple first digital signals, resulting in a first average value; determine an average of the multiple second digital signals, resulting in a second average value; determine an average of the multiple third digital signals, resulting in a third average value; and further wherein to determine, using the one or more first digital signals, the one or more second digital signals, and the one or more third digital signals, the logarithmic ratio of the input current and the reference current, the processor is further configured to: determine, using the first average value, the second average value, and the third average value, the logarithmic ratio of the input current and the reference current.

Example 3. The device of example 1 or example 2, wherein to determine, using the one or more first digital signals, the one or more second digital signals, and the one or more third digital signals, the logarithmic ratio of the input current and the reference current, the processor is further configured to: add a calibration value to a particular one of the one or more first digital signals, resulting in a calibrated digital signal; and determine, based on the calibrated digital signal, a temperature-dependent correction to a difference of a particular one of the one or more second digital signals and a particular one of the one or more third digital signals.

Example 4. The device of any of the preceding examples, wherein the logarithmic transimpedance amplifier device is further configured to generate the analog thermometer signal using sensing circuitry that includes a current digital-to-analog converter that is driven by a digital calibration value.

Example 5. The device of any of the preceding examples, wherein the logarithmic transimpedance amplifier device is further configured to: generate one or more fourth digital signals during a fourth time interval, each of the one or more fourth digital signals corresponding to the analog thermometer signal; generate one or more fifth digital signals during a fifth time interval, each of the one or more fifth digital signals corresponding to an analog voltage signal that is logarithmically proportional to a second input current received at the logarithmic transimpedance amplifier device; and generate one or more sixth digital signals during a sixth time interval, each of the one or more sixth digital signals corresponding to a second analog voltage signal that is logarithmically proportional to a second reference current generated by the logarithmic transimpedance amplifier device; wherein the processor is further configured to determine, using the one or more fourth digital signals, the one or more fifth digital signals, and the one or more sixth digital signals, a logarithmic ratio of the second input current and the second reference current.

Example 6. The device of any of the preceding examples, wherein to generate the one or more first digital signals during the first time interval, the logarithmic transimpedance amplifier device is further configured to sample the analog thermometer signal using a digital-to-analog converter (ADC) device; wherein to generate the one or more second digital signals during the second time interval, the logarithmic transimpedance amplifier device is further configured to sample the analog voltage signal using the ADC device; and wherein to generate the one or more third digital signals during a third time interval, the logarithmic transimpedance amplifier device is further configured to sample the second analog voltage signal using the ADC device.

Example 7. The device of any of the preceding examples, wherein the ADC device is integrated into the logarithmic transimpedance amplifier device.

Example 8. The device of any of the preceding examples, wherein the processor is further configured to: determine, based on the calibrated digital signal, a compensation current; and subtract the compensation current from the input current.

Example 9. The device of any of the preceding examples, wherein the calibration value causes a logarithmic ratio of a first output corresponding to a first input calibration current and a second output corresponding to a second input calibration current to be equal to a logarithmic ratio of the first input calibration current and the second input calibration current, and wherein the first input calibration current is greater than the second input calibration current.

Example 10. The device of any of the preceding examples, wherein the digital calibration value causes a logarithmic ratio of a first output corresponding to a first input calibration current and a second output corresponding to a second input calibration current to be equal to a logarithmic ratio of the first input calibration current and the second input calibration current, and wherein the first input calibration current is greater than the second input calibration current.

Example 11. The device of any of the preceding examples, further comprising a serial interface that functionally couples the logarithmic transimpedance amplifier device with the processor, wherein the serial interface is one of an inter-integrated circuit (I2C) interface, a universal serial bus, or a low-voltage differential signaling (LVDS) interface.

Example 12. The device of any of the preceding examples, wherein the logarithmic transimpedance amplifier device comprises a current generator device configured to generate the reference current.

Example 13. The device of any of the preceding examples, wherein the logarithmic transimpedance amplifier device comprises a current generator device configured to generate the reference current, and further comprises a second current generator device configured to generate the second reference current.

Example 14. The device of any of the preceding examples, wherein the current generator device comprises multiple multiplying current digital-to-analog converter devices configured to receive respective defined digital input values, and wherein the respective defined digital input values cause the current generator device to minimize a deviation of the reference current relative to a designated nominal reference current.

Example 15. The device of any of the preceding examples, wherein the processor is further configured to: determine the input current based on the logarithmic ratio of the input current and the reference current; determine that the input current exceeds a threshold amount; determine a voltage offset by multiplying the input current by an emitter-resistance equivalent value; and subtract the voltage offset from the second analog voltage signal.

Example 16. The device of any of the preceding examples, wherein the processor is further configured to: determine the input current based on the logarithmic ratio of the input current and the reference current; determine a compensation current by evaluating a polynomial function of input current; and add the compensation current to the input current, resulting in a corrected input current that exhibits greater logarithmic conformance than the input current.

Example 17. The device of any of the preceding examples, the logarithmic transimpedance amplifier device being packaged on a single die according to wafer level chip scale package (WLCSP).

Example 18. The device of any of the preceding examples, the logarithmic transimpedance amplifier device, the processor, and the serial interface being packaged on a single die according to wafer level chip scale package (WLCSP).

Example 19. A device, comprising: a logarithmic transimpedance amplifier device configured to: generate multiple first digital signals during respective first time intervals, each one of the multiple first digital signals corresponding to a respective analog thermometer signal that is proportional to a temperature of the logarithmic transimpedance amplifier device; generate multiple second digital signals during respective second time intervals, each one of the multiple second digital signals corresponding to a respective analog voltage signal that is logarithmically proportional to a respective input current received at the logarithmic transimpedance amplifier device; and generate multiple third digital signals during respective third time intervals, each one of the multiple third digital signals corresponding to a respective second analog voltage signal that is logarithmically proportional to a respective reference current generated by the logarithmic transimpedance amplifier device; and a processor functionally coupled with the logarithmic transimpedance amplifier device, the processor being configured to determine, using the multiple first digital signals, the multiple second digital signals, and the multiple third digital signals, respective logarithmic ratios of input current and reference current.

Example 20. The device of example 19, wherein determining, using the multiple first digital signals, the multiple second digital signals, and the multiple third digital signals, the respective logarithmic ratios of input current to reference current comprises: adding a calibration value to a particular one of the multiple first digital signals, resulting in a calibrated digital signal; and determining, based on the calibrated digital signal, a temperature-dependent correction to a difference of a particular one of the multiple second digital signals and a particular one of the multiple third digital signals.

Example 21. A device, comprising: a logarithmic transimpedance amplifier device configured to: generate an analog thermometer signal that is proportional to a temperature of the logarithmic transimpedance amplifier device; generate an analog voltage signal logarithmically proportional to an input current received at the logarithmic transimpedance amplifier device; generate a second analog voltage signal logarithmically proportional to a reference current generated by the logarithmic transimpedance amplifier device; and output the analog thermometer signal, the analog voltage signal, and the second analog voltage signal.

Example 22. The device of example 21 being coupled to a processing unit configured to: generate one or more first digital signals during a first time interval, each of the one or more first digital signals corresponding to the analog thermometer signal; generate one or more second digital signals during a second time interval, each of the one or more second digital signals corresponding to the analog voltage signal; generate one or more third digital signals during a third time interval, each of the one or more third digital signals corresponding to the second analog voltage signal; and determine, using the one or more first digital signals, the one or more second digital signals, and the one or more third digital signals, a logarithmic ratio of the input current and the reference current.

Example 23. The device of example 21 or example 22, wherein the logarithmic transimpedance amplifier device comprises sensing circuitry that includes a current digital-to-analog converter, and wherein generating the analog thermometer signal comprises driving the current digital-to-analog converter with a digital calibration value.

Example 24. The device of any of the preceding examples, wherein the digital calibration value causes a logarithmic ratio of a first output corresponding to a first input calibration current and a second output corresponding to a second input calibration current to be equal to a logarithmic ratio of the first input calibration current and the second input calibration current, and wherein the first input calibration current is greater than the second input calibration current.

Example 25. A system, comprising: a first device configured to: generate an analog thermometer signal that is proportional to a temperature of the first device; generate an analog voltage signal logarithmically proportional to an input current received at the first device; generate a second analog voltage signal logarithmically proportional to a reference current generated by the first device; and output the analog thermometer signal, the analog voltage signal, and the second analog voltage signal; and a second device configured to: receive the analog thermometer signal, the analog voltage signal, and the second analog voltage signal; generate one or more first digital signals during a first time interval, each of the one or more first digital signals corresponding to the analog thermometer signal; generate one or more second digital signals during a second time interval, each of the one or more second digital signals corresponding to the analog voltage signal; generate one or more third digital signals during a third time interval, each of the one or more third digital signals corresponding to the second analog voltage signal; and determine, using the one or more first digital signals, the one or more second digital signals, and the one or more third digital signals, a logarithmic ratio of the input current and the reference current.

Example 26. The system of example 25, further comprising an analog interface that connects the first device and the second device, the analog interface configured to carry the analog thermometer signal, the analog voltage signal, and the second analog voltage signal.

Example 27. The system of example 25 or example 26, the analog interface comprising a pinout assembly, wherein a first pin in the pinout assembly is configured to output the analog voltage signal, and wherein a second pin in the pinout assembly is configured to output the second analog voltage signal, and further wherein a third pin in the pinout assembly is configured to output the analog thermometer signal.

Example 28. The system of any of the preceding examples, wherein the second device comprises a digital-to-analog converter (ADC) device, and wherein to generate the one or more first digital signals during the first time interval, the ADC device is configured to sample the analog thermometer signal; wherein to generate the one or more second digital signals during the second time interval, the ADC device is further configured to sample the analog voltage signal; and wherein to generate the one or more third digital signals during the third time interval, the ADC device is further configured to sample the second analog voltage signal.

Example 29. The system of any of the preceding examples, wherein the second device comprises a processor configured to determine, using the one or more first digital signals, the one or more second digital signals, and the one or more third digital signals, the logarithmic ratio of the input current and the reference current.

Example 30. The system of any of the preceding examples, wherein the one or more first digital signals comprise multiple first digital signals, the one or more second digital signals comprise multiple second digital signals, and the one or more third digital signals comprises multiple third digital signals; and wherein the processor is further configured to: determine an average of the multiple first digital signals, resulting in a first average value; determine an average of the multiple second digital signals, resulting in a second average value; and determine an average of the multiple third digital signals, resulting in a third average value; and further wherein, to determine, using the one or more first digital signals, the one or more second digital signals, and the one or more third digital signals, the logarithmic ratio of the input current and the reference current, the processor is further configured to: determine, using the first average value, the second average value, and the third average value, the logarithmic ratio of the input current and the reference current.

Example 31. The system of any of the preceding examples, wherein to determine, using the one or more first digital signals, the one or more second digital signals, and the one or more third digital signals, the logarithmic ratio of the input current and the reference current, the processor is further configured to: add a calibration value to a particular one of the one or more first digital signals, resulting in a calibrated digital signal; and determine, based on the calibrated digital signal, a temperature-dependent correction to a difference of particular one of the one or more second digital signals and a particular one of the one or more third digital signals.

Example 32. The system of any of the preceding examples, wherein the calibration value causes a logarithmic ratio of a first output corresponding to a first input calibration current and a second output corresponding to a second input calibration current to be equal to a logarithmic ratio of the first input calibration current and the second input calibration current, and wherein the first input calibration current is greater than the second input calibration current.

Example 33. The system of any of the preceding examples, wherein the first device comprises a current generator device configured to generate the reference current.

Example 34. The system of any of the preceding examples, wherein the current generator device comprises multiple multiplying current digital-to-analog converter devices configured to receive respective defined digital input values, and wherein the respective defined digital input values cause the current generator device to minimize a deviation of the reference current relative to a designated nominal reference current.

Example 35. The system of any of the preceding examples, wherein the first device is packaged on a single die according to wafer level chip scale package (WLCSP).

Example 36. A system, comprising: a first device configured to: generate an analog thermometer signal that is proportional to a temperature of the first device; generate analog voltage signals logarithmically proportional to respective input currents received at the first device; generate second analog voltage signals logarithmically proportional to respective reference currents generated by the first device; and output the analog thermometer signal, the analog voltage signals, and the second analog voltage signals; and a second device configured to: receive the analog thermometer signal, the analog voltage signals, and the second analog voltage signals; generate one or more first digital signals during a first time interval, each of the one or more first digital signals corresponding to the analog thermometer signal; generate one or more second digital signals during a second time interval, each of the one or more second digital signals corresponding to a particular one of the analog voltage signals; generate one or more third digital signals during a third time interval, each of the one or more third digital signals corresponding to a particular one of the second analog voltage signals; and determine, using the one or more first digital signals, the one or more second digital signals, and the one or more third digital signals, a logarithmic ratio of a particular one of the respective input currents and a particular one of the respective reference currents.

Example 37. The system of example 36, further comprising an analog interface that connects the first device and the second device, the analog interface configured to carry the analog thermometer signal, the analog voltage signals, and the second analog voltage signals.

Example 38. The system of example 36 or example 37, the analog interface comprising a pinout assembly, wherein first pins in the pinout assembly are configured to output respective ones of the analog voltage signals, and wherein second pins in the pinout assembly are configured to output respective ones of the second analog voltage signals, and further wherein a third pin in the pinout assembly is configured to output the analog thermometer signal.

Example 39. The system of any of the preceding examples, wherein the second device comprises a digital-to-analog converter (ADC) device, and wherein to generate the one or more first digital signals during the first time interval, the ADC device is configured to sample the analog thermometer signal; wherein to generate the one or more second digital signals during the second time interval, the ADC device is further configured to sample the particular one of the analog voltage signals; and wherein to generate the one or more third digital signals during the third time interval, the ADC device is further configured to sample the particular one of the second analog voltage signals.

Example 40. The system of any of the preceding examples, wherein to determine, using the one or more first digital signals, the one or more second digital signals, and the one or more third digital signals, the logarithmic ratio of the particular one of the respective input currents and a particular one of the respective reference currents, the second device is configured to: add a calibration value to a particular one of the one or more first digital signals, resulting in a calibrated digital signal; and determine, based on the calibrated digital signal, a temperature-dependent correction to a difference of a particular one of the one or more second digital signals and a particular one of the one or more third digital signals.

Example 41. The system of any of the preceding examples, wherein the calibration value causes a logarithmic ratio of a first output corresponding to a first input calibration current and a second output corresponding to a second input calibration current to be equal to a logarithmic ratio of the first input calibration current and the second input calibration current, and wherein the first input calibration current is greater than the second input calibration current.

Example 42. The system of any of the preceding examples, wherein the first device comprises multiple current generator devices configured to generate the respective reference currents.

Example 43. The system of any of the preceding examples, wherein a first current generator device of the multiple current generator devices comprises multiple multiplying current digital-to-analog converter devices configured to receive respective defined digital input values, and wherein the respective defined digital input values cause each one of the multiple current generator devices to minimize a deviation of a particular one of the respective reference currents relative to respective designated nominal reference currents.

Example 44. A method, comprising: generating, by a device comprising a logarithmic transimpedance amplifier device and a processor, one or more first digital signals during a first time interval, each of the one or more first digital signals corresponding to an analog thermometer signal that is proportional to a temperature of the logarithmic transimpedance amplifier device; generating, by the device, one or more second digital signals during a second time interval, each of the one or more second digital signals corresponding to an analog voltage signal that is logarithmically proportional to an input current received by the logarithmic transimpedance amplifier device; generating, by the logarithmic transimpedance amplifier device, a reference current; generating, by the device, one or more third digital signals during a third time interval, each of the one or more third digital signals corresponding to a second analog voltage signal that is logarithmically proportional to the reference current; and determining, by the device, using the one or more first digital signals, the one or more second digital signals, and the one or more third digital signals, a logarithmic ratio of the input current and the reference current.

Example 45. The method of example 44, wherein the one or more first digital signals comprise multiple first digital signals, the one or more second digital signals comprise multiple second digital signals, and the one or more third digital signals comprises multiple third digital signals, the method further comprising: determining an average of the multiple first digital signals, resulting in a first average value; determining an average of the multiple second digital signals, resulting in a second average value; and determining an average of the multiple third digital signals, resulting in a third average value; wherein the determining, using the one or more first digital signals, the one or more second digital signals, and the one or more third digital signals, the logarithmic ratio of the input current and the reference current, comprises determining, using the first average value, the second average value, and the third average value, the logarithmic ratio of the input current and the reference current.

Example 46. The method of example 44 or example 45, wherein the determining, using the one or more first digital signals, the one or more second digital signals, and the one or more third digital signals, the logarithmic ratio of the input current and the reference current, comprises: adding a calibration value to a particular one of the one or more first digital signals, resulting in a calibrated digital signal; and determining, based on the calibrated digital signal, a temperature-dependent correction to a difference of a particular one of the one or more second digital signals and a particular one of the one or more third digital signals.

Example 47. The method of any of the preceding examples, further comprising: generating one or more fourth digital signals during a fourth time interval, each of the one or more fourth digital signals corresponding to the analog thermometer signal; generating one or more fifth digital signals during a fifth time interval, each of the one or more fifth digital signals corresponding to an analog voltage signal that is logarithmically proportional to a second input current received at the logarithmic transimpedance amplifier device; generating one or more sixth digital signals during a sixth time interval, each of the one or more sixth digital signals corresponding to a second analog voltage signal that is logarithmically proportional to a second reference current generated by the logarithmic transimpedance amplifier device; and determining, using the one or more fourth digital signals, the one or more fifth digital signals, and the one or more sixth digital signals, a logarithmic ratio of the second input current and the second reference current.

Example 48. The method of any of the preceding examples, wherein the logarithmic transimpedance amplifier device comprises a digital-to-analog converter (ADC) device, and wherein generating the one or more first digital signals during the first time interval comprises sampling, by the ADC device, the analog thermometer signal; wherein generating the one or more second digital signals during the second time interval comprises sampling, by the ADC device, the analog voltage signal; and wherein generating the one or more third digital signals during a third time interval comprises sampling, by the ADC device, the second analog voltage signal.

Example 49. The method of any of the preceding examples, further comprising: determining, based on the calibrated digital signal, a compensation current; and subtracting the compensation current from the input current.

Example 50. The method of any of the preceding examples, wherein the calibration value causes a logarithmic ratio of a first output corresponding to a first input calibration current and a second output corresponding to a second input calibration current to be equal to a logarithmic ratio of the first input calibration current and the second input calibration current, and wherein the first input calibration current is greater than the second input calibration current.

Example 51. The method of any of the preceding examples, wherein the logarithmic transimpedance amplifier device comprises a current generator device having multiple multiplying current digital-to-analog converter devices, the generating the reference current comprises: receiving respective defined digital input values by the multiple multiplying current digital-to-analog converter devices; wherein the respective defined digital input values cause the current generator device to minimize a deviation of the reference current relative to a designated nominal reference current.

Example 52. The method of any of the preceding examples, wherein the logarithmic transimpedance amplifier device comprises a current generator device configured to generate the reference current, and further comprises a second current generator device configured to generate the second reference current.

Example 53. The method of any of the preceding examples, wherein the current generator device comprises multiple multiplying current digital-to-analog converter devices configured to receive respective defined digital input values, and wherein the respective defined digital input values cause the current generator device to minimize a deviation of the reference current relative to a designated nominal reference current.

Example 54. The method of any of the preceding examples, further comprising: determining, by the processor, the input current based on the logarithmic ratio of the input current and the reference current; determining, by the processor, that the input current exceeds a threshold amount; determining, by the processor, a voltage offset by multiplying the input current by an emitter-resistance equivalent value; and subtracting, by the processor, the voltage offset from the second analog voltage signal.

Example 55. The method of any of the preceding examples, further comprising: determining, by the processor, the input current based on the logarithmic ratio of the input current and the reference current; determining, by the processor, a compensation current by evaluating a polynomial function of input current; and adding, by the processor, the compensation current to the input current, resulting in a corrected input current that exhibits greater logarithmic conformance than the input current.

Example 56. A method, comprising: generating, by a logarithmic transimpedance amplifier device, an analog thermometer signal that is proportional to a temperature of the logarithmic transimpedance amplifier device; generating, by the logarithmic transimpedance amplifier device, analog voltage signals logarithmically proportional to respective input currents received at the logarithmic transimpedance amplifier device; generating, by the logarithmic transimpedance amplifier device, second analog voltage signals logarithmically proportional to respective reference currents generated by the logarithmic transimpedance amplifier device; and outputting, by the logarithmic transimpedance amplifier device, the analog thermometer signal, the analog voltage signals, and the second analog voltage signals.

Example 57. The method of example 56, further comprising: generating, by a processing unit, one or more first digital signals during a first time interval, each of the one or more first digital signals corresponding to the analog thermometer signal; generating, by the processing unit, one or more second digital signals during a second time interval, each of the one or more second digital signals corresponding to a particular one of the analog voltage signals; generating, by the processing unit, one or more third digital signals during a third time interval, each of the one or more third digital signals corresponding to a particular one of the second analog voltage signals; and determining, by the processing unit, using the one or more first digital signals, the one or more second digital signals, and the one or more third digital signals, a logarithmic ratio of a particular one of the respective input currents and a particular one of the respective reference currents.

Example 58. The method of example 56 or example 57, wherein the logarithmic transimpedance amplifier device comprises a portion of an analog interface that couples the logarithmic transimpedance amplifier device with the processing unit, the outputting comprising: outputting the analog thermometer signal via a first pin of the analog interface; outputting the analog voltage signals via a second pin of the analog interface; and outputting the second analog voltage signals via a third pin of the analog interface.

Example 59. The method of any of the preceding examples, wherein the processing unit comprises a digital-to-analog converter (ADC) device, and wherein the generating the one or more first digital signals during the first time interval comprises sampling, by the ADC device, the analog thermometer signal; wherein the generating the one or more second digital signals during the second time interval comprises sampling, by the ADC device, the particular one of the analog voltage signals; and wherein the generating the one or more third digital signals during the third time interval comprises sampling, by the ADC device, the particular one of the second analog voltage signals.

Example 60. The method of any of the preceding examples, wherein the one or more first digital signals comprise multiple first digital signals, the one or more second digital signals comprise multiple second digital signals, and the one or more third digital signals comprises multiple third digital signals; the method further comprising: determining an average of the multiple first digital signals, resulting in a first average value; determining an average of the multiple second digital signals, resulting in a second average value; and determining an average of the multiple third digital signals, resulting in a third average value; wherein the determining, using the one or more first digital signals, the one or more second digital signals, and the one or more third digital signals, the logarithmic ratio of the particular one of the respective input currents and the particular one of the respective reference currents comprises determining, using the first average value, the second average value, and the third average value, the logarithmic ratio of the particular one of the respective input currents and the particular one of the respective reference currents.

Example 61. The method of any of the preceding examples, wherein determining, using the one or more first digital signals, the one or more second digital signals, and the one or more third digital signals, the logarithmic ratio of the particular one of the respective input currents and the particular one of the respective reference currents comprises: adding a calibration value to a particular one of the one or more first digital signals, resulting in a calibrated digital signal; and determining, based on the calibrated digital signal, a temperature-dependent correction to a difference of the particular one of the one or more second digital signals and a particular one of the one or more third digital signals.

Example 62. The method of any of the preceding examples, wherein the calibration value causes a logarithmic ratio of a first output corresponding to a first input calibration current and a second output corresponding to a second input calibration current to be equal to a logarithmic ratio of the first input calibration current and the second input calibration current, and wherein the first input calibration current is greater than the second input calibration current.

Example 63. The method of any of the preceding examples, further comprising: determining, by the processing unit, the particular one of the respective input currents based on the logarithmic ratio of the particular one of the respective input currents and the particular one of the respective reference currents; determining, by the processing unit, that the particular one of the respective input currents exceeds a threshold amount; determining, by the processing unit, a voltage offset by multiplying the particular one of the respective input currents by an emitter-resistance equivalent value; and subtracting, by the processing unit, the voltage offset from a particular one of the second analog voltage signals.

Example 64. The method of any of the preceding examples, further comprising: determining, by the processing unit, the particular one of the respective input currents based on the logarithmic ratio of the particular one of the respective input currents and the particular one of the respective reference currents; determining, by the processing unit, a compensation current by evaluating a polynomial function of input current; and adding, by the processing unit, the compensation current to the particular one of the respective input currents, resulting in a corrected input current that exhibits greater logarithmic conformance than the input current.

Various aspects of the disclosure may take the form of an entirely or partially hardware aspect, an entirely or partially software aspect, or a combination of software and hardware. Furthermore, as described herein, various aspects of the disclosure (e.g., systems and methods) may take the form of a computer program product comprising a computer-readable non-transitory storage medium having computer-accessible instructions (e.g., computer-readable and/or computer-executable instructions) such as computer software, encoded or otherwise embodied in such storage medium. Those instructions can be read or otherwise accessed and executed by one or more processors to perform or permit the performance of the operations described herein. The instructions can be provided in any suitable form, such as source code, compiled code, interpreted code, executable code, static code, dynamic code, assembler code, combinations of the foregoing, and the like. Any suitable computer-readable non-transitory storage medium may be utilized to form the computer program product. For instance, the computer-readable medium may include any tangible non-transitory medium for storing information in a form readable or otherwise accessible by one or more computers or processor(s) functionally coupled thereto. Non-transitory storage media can include read-only memory (ROM); random access memory (RAM); magnetic disk storage media; optical storage media; flash memory, and so forth.

Aspects of this disclosure are described herein with reference to block diagrams and flowchart illustrations of methods, systems, devices, and apparatuses. It can be understood that each block of the block diagrams and flowchart illustrations, and combinations of blocks in the block diagrams and flowchart illustrations, respectively, can be implemented by processor-accessible instructions (e.g., processor-readable instructions and/or processor-executable instructions. In certain implementations, the processor-accessible instructions may be loaded or otherwise incorporated into a general purpose computer, a special purpose computer, or another programmable information processing apparatus to produce a particular machine, such that the operations or functions specified in the flowchart block or blocks can be implemented in response to execution at the computer or processing apparatus.

Unless otherwise expressly stated, it is in no way intended that any protocol, procedure, process, or method set forth herein be construed as requiring that its acts or steps be performed in a specific order. Accordingly, where a process or method claim does not actually recite an order to be followed by its acts or steps or it is not otherwise specifically recited in the claims or descriptions of the subject disclosure that the steps are to be limited to a specific order, it is in no way intended that an order be inferred, in any respect. This holds for any possible non-express basis for interpretation, including: matters of logic with respect to the arrangement of steps or operational flow; plain meaning derived from grammatical organization or punctuation; the number or type of aspects described in the specification or annexed drawings; or the like.

As used in this disclosure, including the annexed drawings, the term “component” “module,” “system,” and the like are intended to refer to a computer-related entity or an entity related to an apparatus with one or more specific functionalities. The entity can be either hardware, a combination of hardware and software, software, or software in execution. One or more of such entities are also referred to as “functional elements.” As an example, a component can be a process running on a processor, a processor, an object, an executable, a thread of execution, a program, and/or a computer. For example, both an application running on a server or network controller, and the server or network controller can be a component. One or more components can reside within a process and/or thread of execution and a component can be localized on one computer and/or distributed between two or more computers. Also, these components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which parts can be controlled or otherwise operated by program code executed by a processor. As yet another example, a component can be an apparatus that provides specific functionality through electronic components without mechanical parts, the electronic components can include a processor to execute program code that provides, at least partially, the functionality of the electronic components. As still another example, interface(s) can include I/O components or Application Programming Interface (API) components. While the foregoing examples are directed to aspects of a component, the exemplified aspects or features also apply to a system, module, and similar.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in this specification and annexed drawings should be construed to mean “one or more” unless specified otherwise or clear from context to be directed to a singular form.

In addition, the terms “example” and “such as” are utilized herein to mean serving as an instance or illustration. Any aspect or design described herein as an “example” or referred to in connection with a “such as” clause is not necessarily to be construed as preferred or advantageous over other aspects or designs described herein. Rather, use of the terms “example” or “such as” is intended to present concepts in a concrete fashion. The terms “first,” “second,” “third,” and so forth, as used in the claims and description, unless otherwise clear by context, is for clarity only and doesn't necessarily indicate or imply any order in time or space.

The term “processor,” as utilized in this disclosure, can refer to any computing processing unit or device comprising processing circuitry that can operate on data and/or signaling. A computing processing unit or device can include, for example, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can include an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. In some cases, processors can exploit nano-scale architectures, such as molecular and quantum-dot based transistors, switches and gates, in order to optimize space usage or enhance performance of user equipment. A processor may also be implemented as a combination of computing processing units.

In addition, terms such as “store,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or nonvolatile memory, or can include both volatile and nonvolatile memory. Moreover, a memory component can be removable or affixed to a functional element (e.g., device, server).

Simply as an illustration, nonvolatile memory can include read only memory (ROM), programmable ROM (PROM), electrically programmable ROM (EPROM), electrically erasable ROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

Various aspects described herein can be implemented as a method, apparatus, or article of manufacture using standard programming and/or engineering techniques. In addition, various of the aspects disclosed herein also can be implemented by means of program modules or other types of program instructions (e.g., computer program instructions) stored in a memory device and executed by a processor, or other combination of hardware and software, or hardware and firmware. Such program modules or program instructions (e.g., computer program instructions) can be loaded onto a general purpose computer, a special purpose computer, or another type of programmable data processing apparatus to produce a machine, such that the program modules or program instructions that execute on the computer or other programmable data processing apparatus create a means for implementing the functionality of disclosed herein. Such functionality can be implemented in response to execution of the instructions. The program modules or other types of program instructions thus provide a processor-executable or machine-executable framework to enact the method(s) described herein or a portion thereof. Accordingly, in some cases, a block of the flowchart illustrations described herein and/or combinations of blocks in the flowchart illustrations described herein can be implemented in response to execution of the program modules or other types of program instructions.

The terminology “article of manufacture” as used herein is intended to encompass a computer program or other type of machine instructions stored in and accessible from any processor-readable (e.g., computer-readable device) device, processor-readable carrier, or processor-readable media. For example, processor-readable (e.g., computer readable) media can include magnetic storage devices (e.g., hard drive disk, floppy disk, magnetic strips, or similar), optical discs (e.g., compact disc (CD), digital versatile disc (DVD), blu-ray disc (BD), or similar), smart cards, flash memory devices (e.g., card, stick, key drive, or similar), and other types of memory devices.

What has been described above includes examples of one or more aspects of the disclosure. It is, of course, not possible to describe every conceivable combination of components or methodologies for purposes of describing these examples, and it can be recognized that many further combinations and permutations of the present aspects are possible. Accordingly, the aspects disclosed and/or claimed herein are intended to embrace all such alterations, modifications and variations that fall within the spirit and scope of the detailed description and the appended claims. Furthermore, to the extent that one or more of the terms “includes,” “including,” “has,” “have,” or “having” is used in either the detailed description or the claims, such term is intended to be inclusive in a manner similar to the term “comprising” as “comprising” is interpreted when employed as a transitional word in a claim.

What is claimed is:

1. A method, comprising:
generating, by a device comprising a logarithmic transimpedance amplifier device and a processor, one or more first digital signals during a first time interval, each of the one or more first digital signals corresponding to an analog thermometer signal that is proportional to a temperature of the logarithmic transimpedance amplifier device;
generating, by the device, one or more second digital signals during a second time interval, each of the one or more second digital signals corresponding to an analog voltage signal that is logarithmically proportional to an input current received by the logarithmic transimpedance amplifier device;
generating, by the logarithmic transimpedance amplifier device, a reference current;
generating, by the device, one or more third digital signals during a third time interval, each of the one or more third digital signals corresponding to a second analog voltage signal that is logarithmically proportional to the reference current; and
determining, by the device, using the one or more first digital signals, the one or more second digital signals, and the one or more third digital signals, a logarithmic ratio of the input current and the reference current.

2. The method of claim 1, wherein the one or more first digital signals comprise multiple first digital signals, the one or more second digital signals comprise multiple second digital signals, and the one or more third digital signals comprises multiple third digital signals, the method further comprising:
determining an average of the multiple first digital signals, resulting in a first average value;
determining an average of the multiple second digital signals, resulting in a second average value; and
determining an average of the multiple third digital signals, resulting in a third average value;
wherein the determining, using the one or more first digital signals, the one or more second digital signals, and the one or more third digital signals, the logarithmic ratio of the input current and the reference current, comprises determining, using the first average value, the second average value, and the third average value, the logarithmic ratio of the input current and the reference current.

3. The method of claim 1, wherein the determining, using the one or more first digital signals, the one or more second digital signals, and the one or more third digital signals, the logarithmic ratio of the input current and the reference current, comprises:
adding a calibration value to a particular one of the one or more first digital signals, resulting in a calibrated digital signal; and
determining, based on the calibrated digital signal, a temperature-dependent correction to a difference of a particular one of the one or more second digital signals and a particular one of the one or more third digital signals.

4. The method of claim 1, further comprising:
generating one or more fourth digital signals during a fourth time interval, each of the one or more fourth digital signals corresponding to the analog thermometer signal;
generating one or more fifth digital signals during a fifth time interval, each of the one or more fifth digital signals corresponding to an analog voltage signal that is logarithmically proportional to a second input current received at the logarithmic transimpedance amplifier device;
generating one or more sixth digital signals during a sixth time interval, each of the one or more sixth digital signals corresponding to a second analog voltage signal that is logarithmically proportional to a second reference current generated by the logarithmic transimpedance amplifier device; and
determining, using the one or more fourth digital signals, the one or more fifth digital signals, and the one or more sixth digital signals, a logarithmic ratio of the second input current and the second reference current.

5. The method of claim 1, wherein the logarithmic transimpedance amplifier device comprises a digital-to-analog converter (ADC) device, and wherein generating the one or more first digital signals during the first time interval comprises sampling, by the ADC device, the analog thermometer signal;
wherein generating the one or more second digital signals during the second time interval comprises sampling, by the ADC device, the analog voltage signal; and
wherein generating the one or more third digital signals during a third time interval comprises sampling, by the ADC device, the second analog voltage signal.

6. The method of claim 3, further comprising:
determining, based on the calibrated digital signal, a compensation current; and
subtracting the compensation current from the input current.

7. The method of claim 3, wherein the calibration value causes a logarithmic ratio of a first output corresponding to a first input calibration current and a second output corresponding to a second input calibration current to be equal to a logarithmic ratio of the first input calibration current and the second input calibration current, and wherein the first input calibration current is greater than the second input calibration current.

8. The method of claim 1, wherein the logarithmic transimpedance amplifier device comprises a current generator device having multiple multiplying current digital-to-analog converter devices, the generating the reference current comprises:
receiving respective defined digital input values by the multiple multiplying current digital-to-analog converter devices;
wherein the respective defined digital input values cause the current generator device to minimize a deviation of the reference current relative to a designated nominal reference current.

9. The method of claim 4, wherein the logarithmic transimpedance amplifier device comprises a current generator device configured to generate the reference current, and further comprises a second current generator device configured to generate the second reference current.

10. The method of claim 9, wherein the current generator device comprises multiple multiplying current digital-to-analog converter devices configured to receive respective defined digital input values, and wherein the respective defined digital input values cause the current generator device to minimize a deviation of the reference current relative to a designated nominal reference current.

11. The method of claim 1, further comprising:
determining, by the processor, the input current based on the logarithmic ratio of the input current and the reference current;
determining, by the processor, that the input current exceeds a threshold amount;
determining, by the processor, a voltage offset by multiplying the input current by an emitter-resistance equivalent value; and
subtracting, by the processor, the voltage offset from the second analog voltage signal.

12. The method of claim 1, further comprising:
determining, by the processor, the input current based on the logarithmic ratio of the input current and the reference current;
determining, by the processor, a compensation current by evaluating a polynomial function of input current; and
adding, by the processor, the compensation current to the input current, resulting in a corrected input current that exhibits greater logarithmic conformance than the input current.

13. A method, comprising:
generating, by a logarithmic transimpedance amplifier device, an analog thermometer signal that is proportional to a temperature of the logarithmic transimpedance amplifier device;
generating, by the logarithmic transimpedance amplifier device, analog voltage signals logarithmically proportional to respective input currents received at the logarithmic transimpedance amplifier device;
generating, by the logarithmic transimpedance amplifier device, second analog voltage signals logarithmically proportional to respective reference currents generated by the logarithmic transimpedance amplifier device; and
outputting, by the logarithmic transimpedance amplifier device, the analog thermometer signal, the analog voltage signals, and the second analog voltage signals.

14. The method of claim 13, further comprising:
generating, by a processing unit, one or more first digital signals during a first time interval, each of the one or more first digital signals corresponding to the analog thermometer signal;
generating, by the processing unit, one or more second digital signals during a second time interval, each of the one or more second digital signals corresponding to a particular one of the analog voltage signals;
generating, by the processing unit, one or more third digital signals during a third time interval, each of the one or more third digital signals corresponding to a particular one of the second analog voltage signals; and
determining, by the processing unit, using the one or more first digital signals, the one or more second digital signals, and the one or more third digital signals, a logarithmic ratio of a particular one of the respective input currents and a particular one of the respective reference currents.

15. The method of claim 14, wherein the logarithmic transimpedance amplifier device comprises a portion of an analog interface that couples the logarithmic transimpedance amplifier device with the processing unit, the outputting comprising:
outputting the analog thermometer signal via a first pin of the analog interface;
outputting the analog voltage signals via a second pin of the analog interface; and
outputting the second analog voltage signals via a third pin of the analog interface.

16. The method of claim 14, wherein the processing unit comprises a digital-to-analog converter (ADC) device, and wherein the generating the one or more first digital signals during the first time interval comprises sampling, by the ADC device, the analog thermometer signal;
wherein the generating the one or more second digital signals during the second time interval comprises sampling, by the ADC device, the particular one of the analog voltage signals; and
wherein the generating the one or more third digital signals during the third time interval comprises sampling, by the ADC device, the particular one of the second analog voltage signals.

17. The method of claim 14, wherein the one or more first digital signals comprise multiple first digital signals, the one or more second digital signals comprise multiple second digital signals, and the one or more third digital signals comprises multiple third digital signals; the method further comprising:
determining an average of the multiple first digital signals, resulting in a first average value;
determining an average of the multiple second digital signals, resulting in a second average value; and
determining an average of the multiple third digital signals, resulting in a third average value;
wherein the determining, using the one or more first digital signals, the one or more second digital signals, and the one or more third digital signals, the logarithmic ratio of the particular one of the respective input currents and the particular one of the respective reference currents comprises determining, using the first average value, the second average value, and the third average value, the logarithmic ratio of the particular one of the respective input currents and the particular one of the respective reference currents.

18. The method of claim 14, wherein determining, using the one or more first digital signals, the one or more second digital signals, and the one or more third digital signals, the logarithmic ratio of the particular one of the respective input currents and the particular one of the respective reference currents comprises:
adding a calibration value to a particular one of the one or more first digital signals, resulting in a calibrated digital signal; and
determining, based on the calibrated digital signal, a temperature-dependent correction to a difference of the particular one of the one or more second digital signals and a particular one of the one or more third digital signals.

19. The method of claim 18, wherein the calibration value causes a logarithmic ratio of a first output corresponding to a first input calibration current and a second output corresponding to a second input calibration current to be equal to a logarithmic ratio of the first input calibration current and the second input calibration current, and wherein the first input calibration current is greater than the second input calibration current.

20. The method of claim 14, further comprising:
determining, by the processing unit, the particular one of the respective input currents based on the logarithmic ratio of the particular one of the respective input currents and the particular one of the respective reference currents;
determining, by the processing unit, that the particular one of the respective input currents exceeds a threshold amount;
determining, by the processing unit, a voltage offset by multiplying the particular one of the respective input currents by an emitter-resistance equivalent value; and
subtracting, by the processing unit, the voltage offset from a particular one of the second analog voltage signals.

21. The method of claim 14, further comprising:
determining, by the processing unit, the particular one of the respective input currents based on the logarithmic ratio of the particular one of the respective input currents and the particular one of the respective reference currents;
determining, by the processing unit, a compensation current by evaluating a polynomial function of input current; and
adding, by the processing unit, the compensation current to the particular one of the respective input currents, resulting in a corrected input current that exhibits greater logarithmic conformance than the input current.
